(19) United States
(12) Patent Application Publication
(10) Pub. No.: US 2026/0009160 A1
(43) Pub. Date: Jan. 8, 2026

(54) METHODS OF MANUFACTURE OF TEMPLATES WITH IrNi NANOBRANCHES (NBS), IrNiCu@Cu NANOSTRUCTURES AND ELECTROCATALYSTS COMPRISING IrNiCu@Cu NANOSTRUCTURES, AND APPLICATIONS THEREOF

(71) Applicant: City University of Hong Kong, Hong Kong (HK)

(72) Inventors: Zhanxi FAN, Hong Kong (HK); Yuecheng XIONG, Hong Kong (HK); Yunhao WANG, Hong Kong (HK)

(73) Assignee: City University of Hong Kong, Hong Kong (HK)

(21) Appl. No.: 19/018,282

(22) Filed: Jan. 13, 2025

Related U.S. Application Data
(63) Continuation-in-part of application No. 18/764,392, filed on Jul. 5, 2024.

(51) Int. Cl. C30B 29/62; C25B 11/091; C30B 19/08; C30B 29/02; H01M 8/22

(52) U.S. Cl. CPC C30B 29/62; C25B 11/091; C30B 19/08; C30B 29/02; H01M 8/222

(57) ABSTRACT

The present invention is concerned with the epitaxial growth of unconventional 2H Cu on hexagonal close-packed (hcp) IrNi template, leading to forming of IrNiCu@Cu nanostructures as electrocatalyst. IrNiCu@Cu-20 shows superior catalytic performance, with NH₃ Faradaic efficiency (FE) of 86% at −0.1 (vs reversible hydrogen electrode (RHE)) and NH₃ yield rate of 687.3 mmol gCu−1 h−1, far better than common face-centered cubic (fcc) Cu. IrNiCu@Cu-30 and IrNiCu@Cu-50 covered by hcp Cu shell display high selectivity towards nitrite (NO²⁻), with NO2− FE above 60% at 0.1 (vs RHE). IrNiCu@Cu-20 has the optimal electronic structures for NO₃RR due to the highest d-band center and strongest reaction trend with the lowest energy barriers. The electrocatalysts are effective in electrochemical nitrate reduction NO₃RR.

### CROSS-REFERENCE TO RELATED APPLICATIONS

The application is a Continuation-in-part application from U.S. patent application Ser. No. 18/764,392 filed Jul. 5, 2024 which claims priority from U.S. patent application Ser. No. 63/551,538 filed Feb. 9, 2024, 24, contents of all two earlier filed applications are incorporated herein in their entirety.

### TECHNICAL FIELD OF THE INVENTION

The present invention is concerned with a method of manufacture of templates of IrNi nanobranches (NBS), IrNiCu@Cu nanostructures and electrocatalysts comprising IrNiCu@Cu nanostructures, and applications thereof.

### BACKGROUND OF THE INVENTION

Ammonia (NH₃) is an important chemical commodity with over 150 million tons production annually around the world, and has been widely used in manufacture of fertilizer and other essential chemicals, such as nitric oxide, aviation fuel, organonitrogen compounds, etc. Besides, NH₃ is also emerging as a carbon-free energy carrier due to its high hydrogen content (17.5 wt. %) and can be applied in the electrification of vehicles to reduce carbon emissions. However, the industrial production of NH₃ from air through thermal catalytic procedure (known as the Haber-Bosch process) consumes about 2% of the global energy supply and leaves a significant carbon footprint. In addition, extensive NH₃ and nitrate (NO₃_{^{−}}) derived from Ostwald process are digested by agriculture sectors, which has led to severe nitrate contamination in surface and ground water, remained to be repaired. Recently, electrochemical nitrate reduction (NO₃RR) has emerged as a potential method to produce green NH₃, as it can be driven by renewable energy and adopts electron as the reducing agent, causing no secondary pollution. For thermal catalytic ammonia synthesis, the cleavage of NEN triple bond in dinitrogen has been well recognized as the rate-determining step given its ultrahigh bond energy (941 KJ mol⁻¹). In contrast, the dissociation energy of N═O bond in nitrate is only 204 KJ mol⁻¹, and its solubility in aqueous solution is extremely high. Considering nitrate is widely available from industrial and nuclear wastewater, NO₃RR also provides a strategy to “kill two birds with one stone”, achieving nitrate removal and ammonia production simultaneously. Around 2.2×10¹⁵ L of wastewaters from municipalities, agriculture, and industry are discharged globally every year, and recovering nitrogen resource from wastewaters is profitable as NO₃RR could spread delocalized NH₃ and fertilizer production.

Electrocatalysts play a pivotal role in optimizing and enhancing the performance of electrochemical nitrate reduction reaction (NO₃RR). Metal-based catalysts have shown advantages owing to their superior intrinsic catalytic activity toward nitrate reduction, and copper (Cu) has been found promoting the nitrate conversion to nitrite effectivity. While different materials factors (e.g., defect, crystallinity, strain, and facet) had been explored to uncover the structure-property relationship of electrocatalysts in NO₃RR instability under ambient conditions makes it difficult to prepare unconventional phase (hcp) Cu.

The present invention seeks to address inadequate catalytic activities of conventional (face-centered cubic (fcc)) electrocatalysts and/or at least to provide alternatives to the public.

### SUMMARY OF THE INVENTION

According to a first aspect of the present invention, there is provided a method of manufacture of templates of IrNi nanobranches (NBs) in hexagonal close-packed phase (hcp), comprising the steps in the sequential order of:
adding Iridium acetylacetonate [Ir(acac)₃] and nickel acetylacetonate [Ni(acac)₂] to a combination of oleylamine (OAm)/oleic acid (OA) to form a first mixture,
subjecting the first mixture to ultrasonication to obtain a homogenous solution,
adding formaldehyde (HCHO) to the homogenous solution to form a second mixture, the second mixture being a growth solution,
placing or transferring the growth solution into a container made with an inert material or with an inert lining, and subjecting the growth solution to heating in a reactor,
cooling the growth solution,
harvesting the IrNi NB templates by subjecting the growth solution to centrifugation and washing by an oil removing agent, and
collecting the IrNi NB templates by re-dispersing the IrNi NB templates in a solvent of ethanol.

Preferably, the HCHO solution may be added to the homogenous solution dropwise under stirring or agitation.

Suitably, the oil removing agent may be a mixture of ethanol and hexane with a volume ratio of 2:1 to 1:2 and the centrifugation and washing are conducted 3-4 times. In a particular embodiment, the oil removing agent may be a mixture of ethanol and hexane with a volume ratio of 1:2 and the centrifugation and washing are conducted 3 times.

In an embodiment:
the weight ratio of the Ir(acac)₃ and Ni(acac)₂ may be 1.1:1 to 1:1.1,
the volume ratio of the OAm and OA may be 7.3:1 to 9:1,
the ultrasonication lasts for 1.5-3 hours,
the amount of the HCHO solution used may be 90-00 μL, and
the growth solution may be heated in the reactor from room temperature to a temperature of 200° C.-220° C. and the temperature may be maintained for 10-16 hours.

Studies and experiments leading to the present invention have shown that these parameters are workable ranges.

In a preferred embodiment:
the weight ratio of the Ir(acac)₃ and Ni(acac)₂ may be 1:1,
the volume ratio of the OAm and OA may be 7.3:1,
the ultrasonication may last for 2 hours,
the amount of the HCHO solution used may be 100 μL, and
the growth solution may be heated in the reactor from room temperature to a temperature of 220° C. and the temperature may be maintained for 14 hours.

According to a second aspect of the invention, there is provided a method of manufacture of IrNiCu@Cu nanostructures with Cu in a hexagonal close-packed phase (hcp), comprising, firstly, preparing templates of hexagonal close-packed phase (hcp) of IrNi nanobranches (NBs), the preparing including the steps in the sequential order of adding Iridum acetylacetonate [Ir(acac)₃] and nickel acetylacetonate [Ni(acac)₂] to a combination of oleylamine (OAm)/oleic acid (OA) to form a first mixture, subjecting the first mixture to ultrasonication to obtain a homogenous solution, adding formaldehyde (HCHO) to the homogenous solution to form a second mixture, the second mixture being a growth solution, placing or transferring the growth solution into a container made with an inert material or with an inert lining, and subjecting the growth solution to heating in a reactor, cooling the growth solution, harvesting the IrNi NB templates by subjecting the growth solution to centrifugation and washing by an oil removing agent, and collecting the IrNi NB templates by re-dispersing the IrNi NB templates in a solvent of ethanol; and further comprising, secondly, in the sequential order of obtaining a predetermined quantity of the IrNi NB templates removing the ethanol solvent in which the IrNi NB templates are suspended by way of centrifugation, adding OAm and copper acetylacetonate [Cu(acac)₂] to the IrNi NB templates and forming a homogenous solution, mixing a reducing agent to the homogenous solution to reduce the Cu(acac)₂ solution to Cu, wherein the mixing is conducted by way of oscillation and not ultrasonification, heating the homogenous solution to a predetermined temperature for a predetermined heating duration, allowing growth of the IrNiCu@Cu nanostructures, and isolating reaction products from the homogenous solution by way of centrifugation and/or washing with an oil removing agent, the reaction products being the IrNiCu@Cu nanostructures.

In an embodiment:
the IrNi NB templates may have a mass concentration of 1.8-2 mg mL-1, and the amount of the IrNi NB templates may be 180-200 UL,
the centrifugation to remove the ethanol solvent may be conducted with a speed of 90,000-10,000 rpm for 2-3 mins,
the quantity of OAm may be 1.4-1.5 mL, and the concentration and quantity of Cu(acac)₂ solution may be 80-120 μL and 8-10 mM respectively,
the quantity of the reducing agent may be 80-100 μL,
the predetermined temperature to which the homogenous solution is heated may be 150-120° C. and the predetermined heating duration of 20-50 mins
the volume ratio of ethanol and n-hexane in the ethanol and n-hexane may be 8:1 to 9:1.

in a preferred embodiment:
the IrNi NB templates may have a mass concentration of 2 mg mL-1, and the amount of the IrNi NB templates may be 200 μL,
the centrifugation to remove the ethanol solvent is conducted with a speed of 10,000 rpm for 2 mins,
the quantity of OAm may be 1.5 mL, and the concentration and quantity of Cu(acac)₂ solution may be 100 μL and 10 mM, respectively,
the quantity of the reducing agent may be 100 μL, and
the volume ratio of ethanol and n-hexane in the ethanol and n-hexane may be 9:1.

Studies and experiments leading to the present invention have shown that these parameters are workable ranges.

The predetermined heating time may be 20 mins, 30 mins, or 40 mins. When the predetermined heating time is 20 mins, the electrocatalyst nanostructures produced are addressed as IrNiCu@Cu-20 nanostructures. When the predetermined heating time is 30 mins, the electrocatalyst nanostructures produced are addressed as IrNiCu@Cu-30 nanostructures. When the predetermined heating time is 40 mins, the electrocatalyst nanostructures produced are addressed as IrNiCu@Cu-40 nanostructures.

According to a third aspect of the invention, there is provided a method of making an electrode provided with an electrocatalyst of IrNiCu@Cu nanostructures made from a method as described above, comprising a step of coating the IrNiCu@Cu nanostructure electrocatalyst on the electrode.

According to a fourth aspect of the present invention, there is provided a method of enhancing the performance of electrochemical nitrate reduction reaction (NO₃RR), comprising a step of effecting the NO₃RR by using an electrode made from a method ad described above.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Some embodiments of the present invention will now be explained, with reference to the accompanied drawings, in which:

FIGS. 1A-1I illustrate synthesis and structural characterization of IrNiCu@Cu-20. Specifically, FIG. 1A is a schematic illustration for the epitaxial growth of 2H Cu on hcp IrNi nanobranches; FIGS. 1B-D are HAADF-STEM images of IrNiCu@Cu-20; FIGS. 1E-1F illustrate FFT patterns derived from the marked areas with green and red squares in FIG. 1D; FIG. 1G is an enlarged HAADF-STEM image of IrNiCu@Cu-20 from the marked area in white square in FIG. 1D; FIG. 1H are images of HAADF-STEM (scale bar, 20 nm) and the corresponding EDS elemental mappings of a typical IrNiCu@Cu-20 nano-branch; and FIG. 1I is a graph showing the line-scan profiles of IrNiCu@Cu-20 acquired along the light-yellow line in FIG. 1H.

FIGS. 2A-2L illustrate structural characterization of IrNiCu@Cu-30 and IrNiCu@Cu-50. Specifically, FIG. 2A is an SEM image and FIGS. 2B-2C are HAADF-STEM images of IrNiCu@Cu-30; FIG. 2D illustrates the FFT pattern of FIG. 20; FIG. 2E is a graph illustrating line-scan profiles of IrNiCu@Cu-30 acquired along the light-yellow (horizontal) line in FIG. 2F; FIG. 2F is an HAADF-STEM image (scale bar, 10 nm) and the corresponding EDS elemental mappings of a typical IrNiCu@Cu-30 nano-branch; FIG. 2G is a SEM image and FIGS. 2H-2I are HAADF-STEM images of IrNiCu@Cu-50; FIG. 2J illustrate the FFT pattern of FIG. 2I; FIG. 2K are line-scan profiles of IrNiCu@Cu-50 acquired along the light-yellow (horizontal) line in FIG. 2L; and FIG. 2L is a HAADF-STEM image (scale bar, 10 nm) and the corresponding EDS elemental mappings of a typical IrNiCu@Cu-50 nano-branch.

FIGS. 3A-3G illustrate an X-ray spectral analysis. Specifically, FIG. 3A is a graph showing the Cu 2p XPS spectra of IrNiCu@Cu-20, IrNiCu@Cu-30, IrNiCu@Cu-50 and Cu NPs; FIG. 3B is a graph showing the normalized Cu K-edge XANES spectra of IrNiCu@Cu-20, IrNiCu@Cu-30, IrNiCu@Cu-50 and Cu NPs with the data for reference samples of Cu foil and CuO are included here for comparison; FIG. 3C is a graph showing fourier transform of k²-weighted Cu K-edge EXAFS spectra of IrNi@Cu-20, IrNi@Cu-30, IrNi@Cu-50 and Cu NPs with the data for reference samples of Cu foil and CuO are included here for comparison; FIGS. 1D to 1G are charts showing wavelet transform for the Cu K-edge EXAFS spectra of (d) IrNiCu@Cu-20, (e) IrNiCu@Cu-30, (f) IrNiCu@Cu-50, and (g) Cu NPs, respectively.

FIGS. 4A-4I illustrate the electrochemical nitrate reduction performance; Specifically, FIG. 4A is a graph showing the LSV curves of IrNiCu@Cu-20, IrNiCu@Cu-30 and IrNiCu@Cu-50 at 5 mV s⁻¹ with 85% IR compensation; FIGS. 4B-4C are graphs showing the FEs of NHs and NO₂⁻, respectively, and the NH₃ yield rates of IrNiCu@Cu-20, IrNiCu@Cu-30 and IrNiCu@Cu-50 based on constant potential electrolysis, respectively; FIG. 4D is a graph showing the NHs FEs of IrNiCu@Cu-20 quantified by UV-vis and NMR methods at −0.1 V (vs RHE); FIG. 4E is a graph showing the 1H NMR spectra of electrolytes after NO₃RR using nitrate-free solution, K¹⁴NO₃ and K¹⁵NO₃; FIG. 4F is a graph showing the NH₃ FEs and yield rates of IrNiCu@Cu-20 and IrNiCu@Cu-30 at −0.1 V (vs RHE) during 15 consecutive cycles; FIG. 4G is a graph showing the real-time concentration changes of NO₃_{^{−}}, NO₂_{^{−}} and NH₃ during nitrate reduction using IrNiCu@Cu-20 and IrNiCu@Cu-30 as the electrocatalysts; FIGS. 4H-4I are graphs showing the in-situ DEMS patterns of IrNiCu@Cu-20 and IrNiCu@Cu-30, respectively, during electrocatalytic nitrate reduction based on 5 consecutive LSV scans.

FIGS. 5A-5N illustrate theoretical studies of IrNiCu@Cu nanostructures of the presentation invention. Specifically, FIGS. 5A-5C are schematic diagrams showing the electronic distributions of bonding and anti-bonding orbitals near the Fermi level of fcc Cu, IrNiCu@Cu-20, and IrNiCu@Cu-30, respectively, with orange balls representing Cu, blue balls presenting Ni, and purple balls representing Ir, and blue iso-surfaces representing bonding orbitals and green iso-surfaces representing anti-bonding orbitals. FIGS. 5D-5F are graphs showing the PDOS of fcc Cu, IrNiCu@Cu-20, and IrNiCu@Cu-30, respectively; FIG. 5G is a graph showing the d-band center comparison of fcc Cu, IrNiCu@Cu-20, and IrNiCu@Cu-30; FIG. 5H is a graph showing the site-dependent PDOSs of Cu-3d in fcc Cu and IrNiCu@Cu-20, with INC@C-20 and INC@C-30 represent IrNiCu@Cu-20 and IrNiCu@Cu-30, respectively; FIG. 5I is a graph showing the site-dependent PDOS of Cu-3d in IrNiCu@Cu-30; FIGS. 5J-5K showing the PDOS of key intermediates of NO₃RR in IrNiCu@Cu-20 and IrNiCu@Cu-30, respectively; FIG. 5I is an graph showing the adsorption energies of NO₃_{^{−}} and H*, FIG. 5M is a graph showing the reaction energy changes of NO₃RR; and FIG. 5N is a graph showing the reaction energy changes of HER.

FIGS. 6A-6D shows Zn-NO₃_{^{−}} battery demonstration. Specifically, FIG. 6A is a graph illustrating an open circuit potential of Zn-NO₃_{^{−}} batteries constructed with IrNiCu@Cu-20 and IrNiCu@Cu-30 (Insets: the digital photographs elucidating the battery device and its ability to power an electronic timer); FIG. 6B is a graph illustrating discharging polarization profiles and the corresponding power density curves; FIG. 6C is a graph showing the rate capabilities of Zn-NO₃_{^{−}} batteries during discharging; FIG. 6D is a graph showing a galvanostatic discharge profiles of Zn-NO₃_{^{−}} batteries from OCV to 0.005 V (vs Zn²⁺/Zn) at the current density of 1 and 1.5 mA cm⁻² using IrNiCu@Cu-20 as cathode.

FIGS. 7A-7F illustrate characterization of fcc Cu nanoparticles (Cu NPs). Specifically, FIGS. 7A-7B are SEM image and relevant EDS spectrum of Cu NPs, respectively, FIGS. 7C-7E are TEM image, size distribution and SAED pattern of Cu NPs, respectively; and FIG. 7F is a graph showing the powder XRD pattern of Cu NPs.

FIG. 8A is a TEM image of hcp IrNi template; and FIG. 8B is an image showing a SAED of the hcp IrNi template.

FIGS. 9A-9B are graphs showing the average Cu shell thickness of IrNiCu@Cu-30 and IrNiCu@Cu-50, respectively, based on data obtained from TEM images and Gauss fitting results.

FIG. 10 is a graph showing Ir 4f XPS spectra of IrNi, IrNiCu@Cu-20, IrNiCu@Cu-30, and IrNiCu@Cu-50.

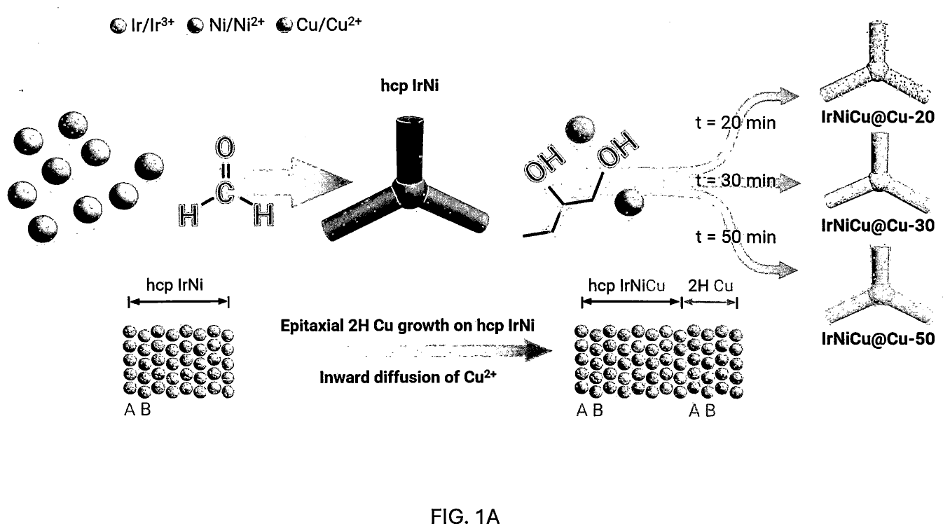

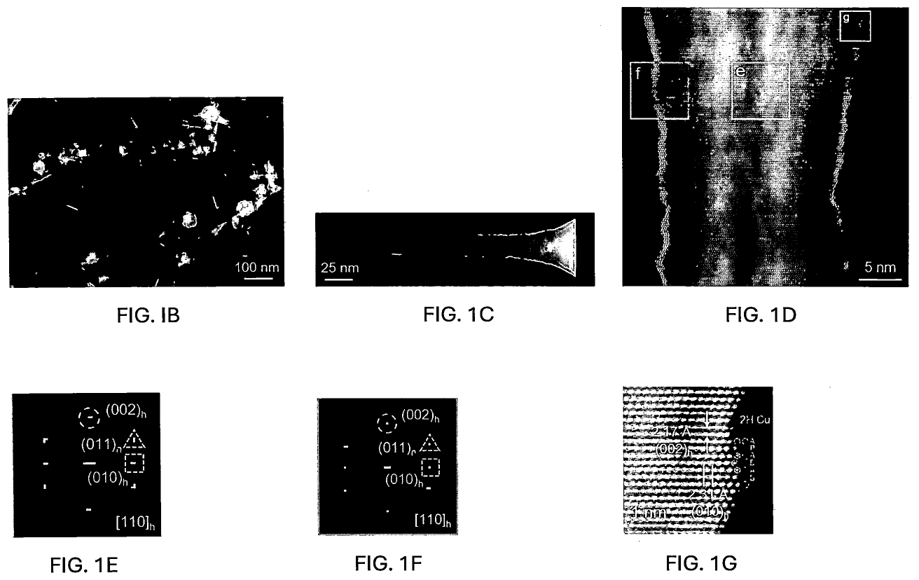

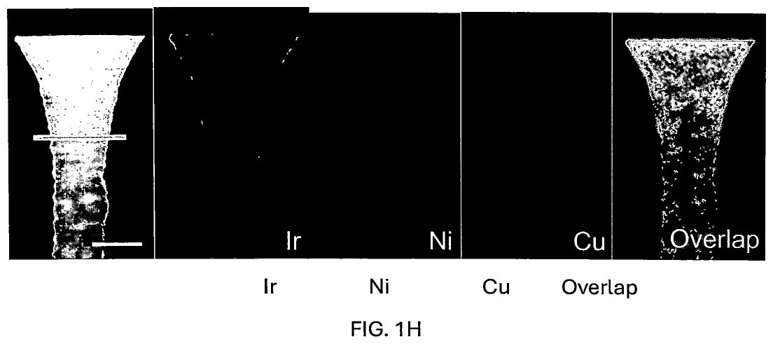

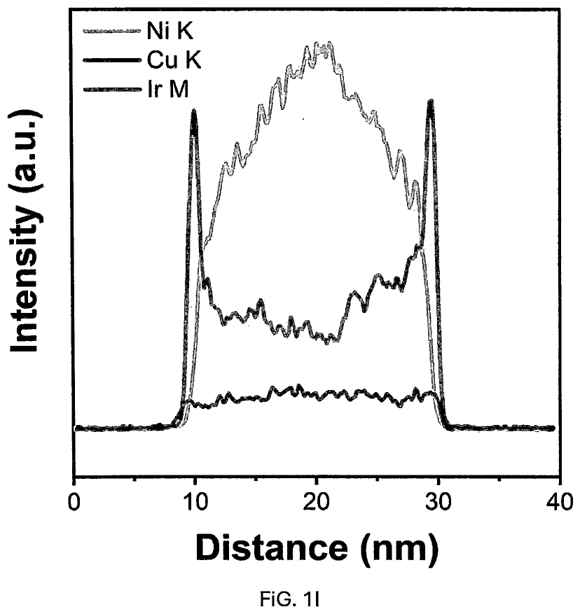

FIG. 1I is a graph showing Ni 2p XPS spectra of IrNi, IrNi@Cu-20, IrNi@Cu-30, and IrNi@Cu-50.

FIG. 12A is a graph showing normalized Ir Ls-edge XANES spectra of IrNiCu@Cu-20, IrNiCu@Cu-30, and IrNiCu@Cu-50 in reference to Ir foil and IrO₂; and FIG. 12B is a showing Fourier transform of k²-weighted EXAFS spectra of IrNiCu@Cu-20, IrNiCu@Cu-30, and IrNiCu@Cu-50 in reference to Ir foil and IrO₂.

FIG. 12C is a graph showing normalized Ni K-edge XANES spectra of IrNiCu@Cu-20, IrNiCu@Cu-30, and IrNiCu@Cu-50 in reference to Ni foil and NiO; and FIG. 12D is a graph showing fourier transform of k²-weighted EXAFS spectra of IrNiCu@Cu-20, IrNiCu@Cu-30, and IrNiCu@Cu-50 in reference to Ni foil and NiO.

FIG. 13 is a graph showing Cu LMM AES spectra of IrNiCu@Cu-20, IrNiCu@Cu-30, IrNiCu@Cu-50, and Cu NPs.

FIG. 14 is a chart showing EXAFS fitting results of k2-weighted R space Cu K-edge of IrNiCu@Cu-20, IrNiCu@Cu-30, IrNiCu@Cu-50, and fcc Cu NPs.

FIG. 15 is a chart showing wavelet transform for the Cu K-edge EXAFS spectra of standard Cu foil.

FIGS. 16A-16B are graphs showing LSV profiles of IrNiCu@Cu-20 and IrNiCu@Cu-30, respectively, tested in 0.1 M NO3−+0.1 M KOH with different mass loadings of Cu; and FIGS. 16C-16D are graphs showing LSV profiles of IrNiCu@Cu-20 and IrNiCu@Cu-30, respectively, tested in different pH with the Cu mass loading of 200 μg cm−2; in that the LSV measurements were conducted without iR compensation.

FIGS. 17A & 17C are graphs showing the effect of Cu mass loading (50, 100, 200 μg) on NO₃RR performance using IrNiCu@Cu-20 as electrocatalysts in 0.1 M KOH with 0.1 M KNO₃; and FIGS. 17B & 17D are graphs showing the effect of Cu mass loading (50, 100, 200 μg) on NO₃RR performance using IrNiCu@Cu— as electrocatalysts in 0.1 M KOH with 0.1 M KNO₃; in that measurements were carried out for three times and the mean values are plotted.

FIGS. 18A & 18C are graphs showing the effect of pH (12, 13, 14) on NO₃RR performance using IrNiCu@Cu-20 as electrocatalysts with 0.1 M KNO₃; and FIGS. 18B & 18D are graphs showing the effect of pH (12, 13, 14) on NO₃RR performance using IrNiCu@Cu-30 as electrocatalysts with 0.1 M KNO₃; in that measurements were carried out for three times and the mean values are plotted.

FIGS. 19A-19B are graphs of calibration curve of NH₄_{⁺} using NH₄Cl as standards. Specifically, FIG. 19A illustrates UV-vis absorption spectra of different NH₄_{⁺} concentrations and FIG. 19B illustrates linear fitting results of the calibration curve.

FIGS. 20A-20B are graphs of calibration curve of NO₂_{^{−}} using KNO₂ as standards. Specifically, FIG. 20A illustrates UV-vis absorption spectra of different NO₂_{^{−}} concentrations and FIG. 20B illustrates linear fitting results of the calibration curve.

FIGS. 21A-21B are graphs showing calibration curve of NO₃_{^{−}} using KNO₃ as standards. Specifically, FIG. 21A illustrates UV-vis absorption spectra of different NO₃_{^{−}} concentrations and FIG. 21B illustrates linear fitting results of the calibration curve.

FIGS. 22A and 22B are graphs showing the NH₃ and NO₂_{^{−}} FEs using pristine IrNi and fcc Cu NPs, respectively, as electrocatalysts in 0.1 M KOH with 0.1 M KNO₃, in that measurements were carried out for three times and the mean values are plotted.

FIG. 23 is a graph of EDS spectra of IrNiCu@Cu-20, IrNiCu@Cu-30, and IrNiCu@Cu-50.

FIG. 24 is a graph showing Cu atomic percentage of IrNiCu@Cu-20, IrNiCu@Cu-30, and IrNiCu@Cu-50 based on EDS results.\

FIGS. 25A & 25B are graphs showing the chronoamperometric curves during electrolysis under different electrode potentials using IrNiCu@Cu-20 and IrNiCu@Cu-30, respectively, as electrocatalysts.

FIGS. 26A, 26B and 26C are graphs showing, respectively, a) LSV profiles with 85% iR compensation, b) Faradaic efficiencies, and c) NH₃ yield rates of IrNiCu@Cu-20 and IrNiCu@Cu-30 in 0.01 M NO₃_{^{−}} with 0.1 M KOH electrolyte; and FIGS. 26D, 26E and 26F are graphs, showing, respectively, d) LSV profiles with 85% iR compensation, e) Faradaic efficiencies, and f) NH₃ yield rates of IrNiCu@Cu-20 and IrNiCu@Cu-30 in 1 M NO₃_{^{−}} with 0.1 M KOH electrolyte.

FIGS. 27A & 27B are heatmaps of NH₃ FE over a) IrNiCu@Cu-20 and b) IrNiCu@Cu-30, respectively; FIGS. 27C & 27D are heatmaps of NHs yield rate over c) IrNiCu@Cu-20 and d) IrNiCu@Cu-30, respectively; and FIGS. 27E & 27F are heatmaps of NO₂_{^{−}} FE over e) IrNiCu@Cu-20 and f) IrNiCu@Cu-30, respectively.

FIG. 28A is a graph of the ¹H NMR spectra of ¹⁴NH₄_{⁺} with a series of ¹⁴NH₄Cl concentrations using C₄H₄O₄ as internal standards; and FIG. 28B is a graph showing the calibration curve according to the integral area of ¹⁴NH₄_{⁺}/C₄H₄O₄ versus the concentration of ¹⁴NH₄_{⁺}.

FIG. 29A is a graph of the ¹H NMR spectra of ¹⁵NH₄_{⁺} with a series of ¹⁵NH₄Cl concentrations using C₄H₄O₄ as internal standards; and FIG. 29B is a graph showing the calibration curve according to the integral area of ¹⁵NH₄_{⁺}/C₄H₄O₄ versus the concentration of ¹⁵NH₄_{⁺}.

FIG. 30 is a chart showing in-situ DEMS patterns of IrNiCu@Cu-50 during electrocatalytic nitrate reduction based on 4 consecutive LSV scans from 0.2 to −0.7 V (vs RHE).

FIG. 31A is a graph showing working electrode potential profile of continuous 24-h electrolysis at constant current of 100 mA cm-2 using IrNiCu@Cu-20 as the catalyst; and FIG. 31B is a graph showing the concentration of NO₃_{^{−}}, NO₂_{^{−}}, and NH₃ concentration change during the 24-h electrolysis process.

FIG. 32 is a graph showing the discharging polarization profile and the corresponding power density curve of Zn-NO₃_{^{−}} battery using IrNiCu@Cu-20 as the cathode (catholyte composition: 0.1 M NO₃_{^{−}}+0.1 M KOH+0.2 M K₂SO₄).

FIG. 33A and FIG. 33B are graphs, respectively, showing discharging polarization profiles and the corresponding power density curves of Zn-NO₃_{^{−}} battery using IrNiCu@Cu-20 as the cathode in different catholytes with a) 0.01 M NO₃_{^{−}} and b) 1 M NO₃_{^{−}}.

FIG. 34 is a schematic diagram showing an unconventional phase (hcp) 2H Cu synthesized through epitaxial growth on hop IrNi template, and the distribution of 2H Cu is well regulated by controlling reaction time, resulting in three kinds of IrNiCu@Cu nanostructures. Notably, IrNiCu@Cu-20 with low Cu coverage demonstrates superior ammonia yield rate toward nitrate electroreduction, which is 3.6 times that of IrNiCu@Cu-50 with high Cu coverage.

### DETAILED DESCRIPTION OF PREFERRED EMBODIMENTS OF THE INVENTION

Electrochemical nitrate reduction reaction (NO₃RR) is emerging as a promising strategy for nitrate removal and ammonia (NH₃) production using renewable electricity. Although there has been progress in developing strategies in NO₃RR, the crystal phase effect of electrocatalysts on NO₃RR remains rarely explored and largely unknown. Research and development leading to the present invention shows that the epitaxial growth of unconventional 2H Cu on hexagonal close-packed (hcp) IrNi template, resulting in the formation of three IrNiCu@Cu nanostructures. For example, IrNiCu@Cu-20 shows superior catalytic performance, with NH₃ Faradaic efficiency (FE) of 86% at −0.1 (vs reversible hydrogen electrode (RHE)) and NH₃ yield rate of 687.3 mmol g_{Cu}⁻¹ h⁻¹, far better than conventional phase (common face-centered cubic-fcc) Cu. In sharp contrast, IrNiCu@Cu-30 and IrNiCu@Cu-50 covered by hcp Cu shell display high selectivity towards nitrite (NO₂_{^{−}}), with NO₂_{^{−}} FE above 60% at 0.1 (vs RHE). Theoretical calculations have demonstrated that the IrNiCu@Cu-20 has the optimal electronic structures for NO₃RR due to the highest d-band center and strongest reaction trend with the lowest energy barriers. The high electroactivity of IrNiCu@Cu-20 originates from the abundant low coordination of Cu sites on the surface, which guarantees the fast electron transfer to accelerate the intermediate conversions. The present invention provides a feasible tactic to regulate the product distribution of NO₃RR by crystal phase engineering of electrocatalysts.

Extensive experiments and studies leading to the present invention are described below.

### Materials and Methods

### Chemicals and Reagents

Iridium (III) acetylacetonate (Ir(acac)₃, 99%) and sodium nitroprusside (C₅H₄FeN₆Na₂O₃) were purchased from Alfa Aesar. Oleic acid (OA, 99%) was purchased from Sigma-Aldrich. Solution of sodium hypochlorite (NaClO, 0.1 M) was purchased from Macklin. Nickel (II) acetylacetonate (Ni(acac)₂, 95%), oleylamine (OAm, 80-90%), formaldehyde (HCHO, 37 wt. % in H₂O), isopropyl alcohol (IPA, AR, ≥99.5%), potassium hydroxide (KOH, AR, 99%), potassium nitrate (KNO₃, AR, 99%), ammonium chloride (ACS, 99.5%), salicylic acid (AR, 99.5%), trisodium citrate dihydrate (98%), sodium hydroxide (NaOH, AR, 96%), maleic acid (AR, ≥99.0% (HPLC)), and deuterium oxide (D₂O, AR, 99%) were supplied by Shanghai Aladdin Biochemical Technology Co., Ltd. Ethanol (absolute, ≥99.9%) and hexane (99%) were obtained from Anaqua Global International Inc. Limited. All the chemicals and reagents were used as received without further purification. Deionized (DI) water used in the experiments was obtained from the Milli-Q Plus System with a resistance of 18.2 MΩ cm.

### Synthesis of hcp IrNi Template

Preparation of IrNi firstly involved the use of 4 mg of Ir(acac)₃ and 4 mg of Ni(acac)₂ added into 12 mL glass vial, and then 4.5 mL of OAm and 0.5 mL of OA were added into the system. Until a homogeneous solution formed, 100 μL of formaldehyde were added. After stirring for about 15 mins, 2.5 mL of mixed solution were added into 4 mL glass vial, which was subsequently moved to autoclave. The reaction last for 12 h under 220° C., and the sample was collected by centrifugation. After rinsing by mixed solvent of ethanol and n-hexane for several times, the sample was obtained and stored in ethanol.

Synthesis of Unconventional Phase (hcp) IrNiCu@Cu Nanostructures

Typically, 200 μL of hcp IrNi template with a mass concentration of 2 mg mL⁻¹ were taken and the solvent was discarded after centrifugation. Then, 1.5 mL of OAm and 100 μL of Cu(acac)₂ solution (10 mM) were added into the glass bottle to make a homogeneous solution. Afterwards, 100 μL of 1,2-butanediol were added. Using the oscillator instead of ultrasonication to mix the solution to avoid the pre-reduction of Cu²⁺. The glass bottle was sealed and put into the oil bath under the temperature of 120° C., and the reaction time was controlled as 20, 30, and 50 mins, respectively. After reaction, the sample was acquired by centrifugation and washed with the mixture of ethanol/n-hexane (v/v=9/1) for several times. The obtained samples were denoted as IrNiCu@Cu-20, IrNiCu@Cu-30, and IrNiCu@Cu-50 based on reaction periods and stored in ethanol for further use.

### Synthesis of fcc Cu Nanoparticles

2 mL of Cu(acac)₂ solution (40 mM) were put into a glass bottle, and then 500 μL of 1,2-butanediol were added to make a homogeneous solution. After reaction under 170° C. for 12 h, the product was separated by centrifugation, and washed with ethanol for several times. Then, the obtained fcc Cu nanoparticles were stored in ethanol for further use.

### Characterization

The transmission electron microscope (TEM) and high-resolution TEM (HRTEM) images were taken on a JEOL-2100F transmission electron microscope operated at 200 kV. The spherical aberration-corrected high-angle annular dark-field scanning TEM (HAADF-STEM) images were obtained on a high-resolution aberration-corrected TEM (JEOL JEM-ARM200F). Scanning electron microscope (SEM) measurements were conducted on QUANTA 250. X-ray photoelectron spectroscopy (XPS) test was performed on Thermo Scientific Nexsa spectrophotometer with Al-Kα radiation system. The calibration of the data was performed by using the C 1s peak at 284.8 eV. X-ray absorption spectroscopy (XAS) measurement was conducted in a transmission mode at beamline X-ray absorption fine structure for catalysis (XAFCA) of Singapore Synchrotron Light Source. The data processing was performed with the Athena and Artemis software packages. In-situ differential electrochemical mass spectrometry (DEMS) test was performed on the Linglu DEMS analysis system from Shanghai Linglu Instrument Co., Ltd.

### Electrochemical Nitrate Reduction Tests

The preparation of working electrode. The catalysts dispersed in ethanol were further washed with ethanol to remove the remaining surfactants. Then, 2 mg of the catalysts (Note that the mass was based on Cu) were re-dispersed into 1 mL of isopropanol, followed by adding 20 μL of Nafion solution to make a homogeneous suspension (2 mg_{Cu} mL⁻¹). Subsequently, it was ultrasonicated for about 2 h to enable the well dispersion of catalyst inks. Afterwards, certain amounts (e.g., 25, 50, and 100 μL) of catalyst inks were dropped onto the carbon paper with an area of 1 cm² (1 cm×1 cm).

NO₃RR test. The electrochemical NO₃RR performance test was performed in a H-type cell separated by a proton exchange membrane (Nafion 117). The catalyst-modified carbon paper, Pt plate, and Ag/AgCl (filled with saturated KCl) were used as the working, counter, and reference electrodes, respectively. All the potentials were converted to the reversible hydrogen electrode (RHE) based on the equation: E (vs RHE)=E (vs Ag/AgCl)+0.197 V+0.059×pH. The solution containing different concentrations of KOH (e.g., 0.01 M, 0.1 M, and 1 M) and 0.1 M KNO₃ were used as the electrolyte, which was purged with high purity argon (Ar) for at least 30 mins before the test. Then, 25 mL of electrolyte were added into both the anode and cathode compartments of the H-type cell. The linear sweep voltammetry (LSV) curves were acquired at a scan rate of 5 mV s⁻¹. The chronoamperometry test was conducted for 1 h at each potential under a stirring rate of 600 rpm with 85% iR compensation. All electrochemical tests were done with Ivium-n-Stat electrochemical workstation.

### Detection of Products and Reactants

NH₃/NH₄_{⁺} detection. Indophenol blue method was used. In detail, 1 mL of electrolyte was taken out after test and diluted with distilled water at suitable folds. Firstly, 2.5 mL of solution A (composed of 0.625 M NaOH, 0.36 M salicylic acid and 0.17 M sodium citrate) were added. Then 300 μL of solution B (sodium nitroferricyanide, 10 mg mL⁻¹) and 150 μL of solution C (NaClO, active chlorine 6-14 wt. %) were added, successively. After homogeneous mixing, the solution was kept without disturbance for 2 h under dark environment. Next, UV-vis spectrophotometry (Shimadzu-UV1700) was used to examine the absorbance values at 660 nm of these mixed solutions, and the NH₃ concentrations can be obtained according to the calibration curves. The amount of generated NH₃ was also calculated by 1H NMR method. 1 mL of electrolyte after NO₃RR was added with 10 μL of C₄H₄O₄ which acted as the internal standards. After that, 50 μL of 4 M H₂SO₄ were further introduced to provide a weak acid environment. Subsequently, 450 μL of the above solution were mixed with 50 μL of D₂O for NMR tests. The integral peak area ratios between NH₄_{⁺} and C₄H₄O₄ were calculated and the corresponding NH₄_{⁺} concentrations can be determined according to the standard curve. The standard NH₄_{⁺} solutions with given concentrations of (NH₄)₂SO₄ in 0.05 M H₂SO₄ were prepared to establish the calibration curves for UV-vis and NMR methods. As for the ¹⁵N-labeling experiments, all the electrochemical operations and quantitative analysis were the same except for using ¹⁵KNO₃ as the nitrogen sources.

NO₂_{^{−}} detection. Firstly, 4 g of p-aminobenzenesulfonamide, 0.2 g of N-(1-Naphthyl)ethylenediamine dihydrochloride, and 10 mL of phosphoric acid (density=1.70 g mL⁻¹) were added into 50 mL of ultrapure water. After ultrasonication, the obtained transparent solution was used as the coloring reagent. Then, 5 mL of diluted electrolyte were mixed with 0.1 mL of coloring reagent. After 20 mins, the absorption spectrum was taken at the wavelength of 540 nm. A series of standard potassium nitrite solutions were prepared to obtain the calibration curve.

NO₃⁻ detection. Firstly, a certain amount of electrolyte was taken out from the electrolytic cell and diluted to 5 mL for measurement. Then, 0.1 mL of 1 M HCl solution and 0.01 mL of 0.8 wt. % sulfamic acid solution were added into the solution to be tested. The absorption spectra were measured at a wavelength of 220 nm and 275 nm, and the final absorbance value was calculated according to the equation: A=A_{220 nm}−2*A_{275 nm}. The concentration-absorbance curve was calibrated using a series of standard potassium nitrate solutions and potassium nitrate was dried before use.

### Calculation of Faradaic Efficiency (FE) and Yield Rate

Herein, the FEs of NH₃ and NO₂_{^{−}} were calculated based on the following equations:

$${NH}_{3} FE = ( 8 \times F \times {C}_{{NH}_{3}} \times V ) / ( {M}_{N {H}_{3}} \times Q ) \times 100 \%$$

$${NO}_{{2}^{-}} FE = ( 2 \times F \times {C}_{{NH}_{{2}^{-}}} \times V ) / ( {M}_{N {H}_{{2}^{-}}} \times Q ) \times 100 \%$$

The yield rate of NH₃ was calculated based on the following equation:

$${NH}_{3} yield rate = ( {C}_{{NH}_{3}} \times V ) / ( {m}_{Cu} \times t ) ,$$

where F is the Faraday constant (96485 C mol⁻¹), C_{NO}_{₂}₋ and C_{NH}_{₃} represent the concentration of NO₂_{^{−}} and NH₃ (mg L⁻¹), V is the volume of the electrolyte (L), M_{NO}_{₂}₋ and MNH, are the molar mass of NO₂_{^{−}} and NH₃ (g mol⁻¹), Q is the total amount of charge (C), mcu is the mass of Cu loading (mg), and t is the electrolysis time (h).

### Assembly of Zn-Nitrate Battery

A typical H-type cell separated by a bipolar membrane was utilized to assemble the Zn-NO₃_{^{−}} battery. The catalyst supported on carbon paper and a polished Zn foil were used as the working and counter electrodes, respectively. 25 mL of electrolyte composed of 0.1 M KOH and 0.1 M KNO₃ were added into the cathode compartment, while 25 mL of electrolyte composed of 1 M KOH and 0.02 M Zn(Ac)₂ (Ac=acetate) were added into the anode compartment. The discharging curve was recorded by an Ivium-n-Stat electrochemical workstation with the sweep rate of 5 mV s⁻¹. The galvanostatic discharge-charge curves were collected with the constant current. The galvanostatic tests with different current densities were performed for 1 h at room temperature using LAND battery test system (CT2001A, Wuhan LAND Electronic Co. Ltd).

### Calculation Setup

In the present invention, density functional theory (DFT) calculations based on the CASTEP package were applied to investigate electronic structures and reaction trends of NO₃RR. For the functionals, the generalized gradient approximation (GGA) and Perdew-Burke-Ernzerhof (PBE) functionals were applied, thus allowing the supplying of accurate descriptions of the exchange-correlation interactions. For all the geometry optimizations, the plane-wave cutoff energy has been set to 440 eV, and the ultrasoft pseudopotentials were applied. Broyden-Fletcher-Goldfarb-Shannon (BFGS) has been selected as the algorithm for energy minimization. In addition, the coarse quality for the k-point was chosen. The IrNi@Cu₂₀ and IrNi@Cu₃₀ models have been built based on the hcp IrNi structures with 7-layer thickness. For all the surfaces, 20 Å vacuum space has been introduced in the z-axis to guarantee complete relaxation. The following convergence criteria were applied to guarantee the geometry optimizations including: 1) the Hellmann-Feynman forces should be converged to less than 0.001 eV/Å; 2) the total energy difference should be converged to smaller than 5×10−5 eV/atom; and 3) the maximum displacement for each atom should be smaller than 0.005 Å.

### Results and Discussion

### Structural Characterizations of Unconventional Phase IrNiCu@Cu Catalysts

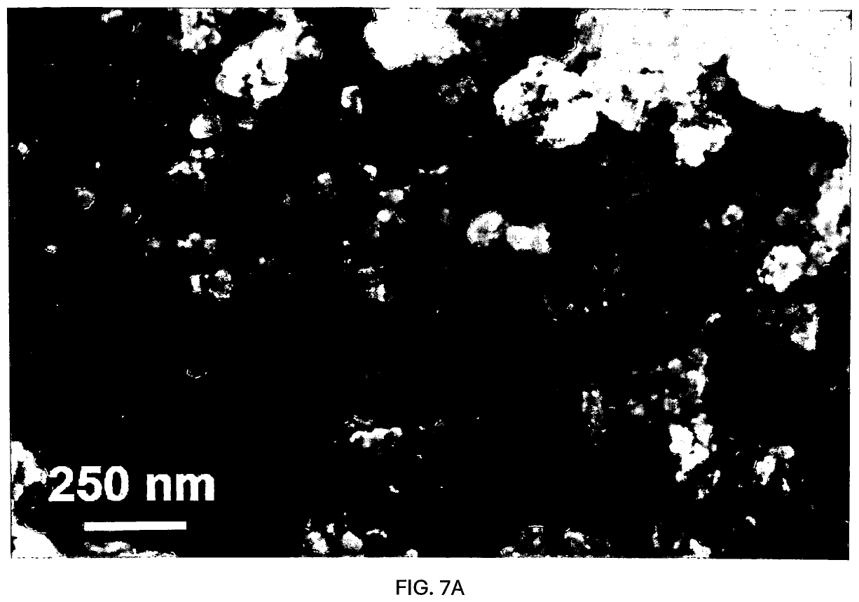

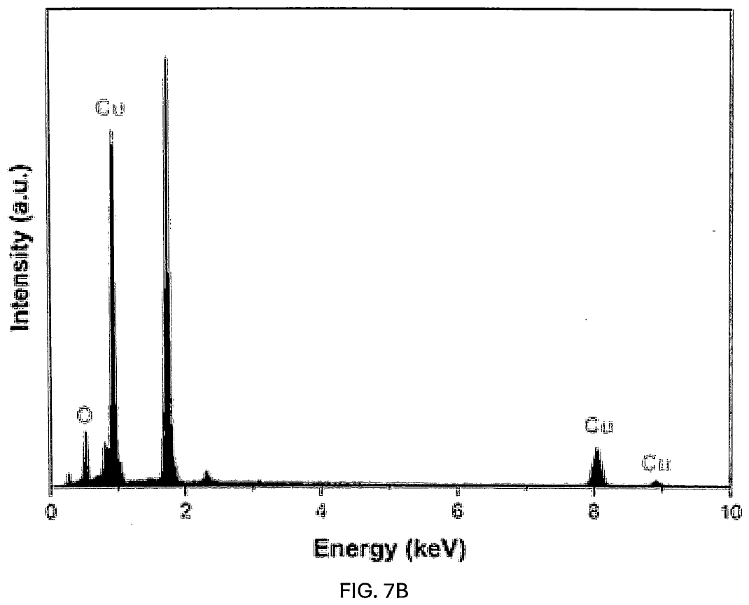

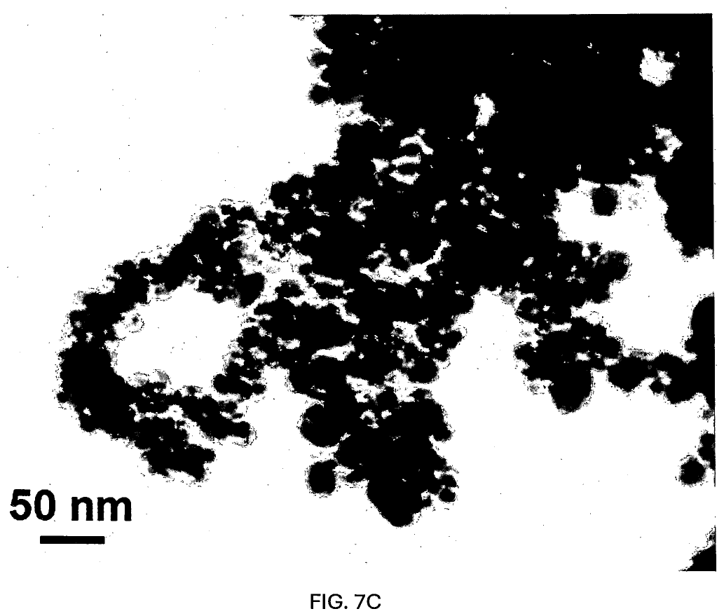

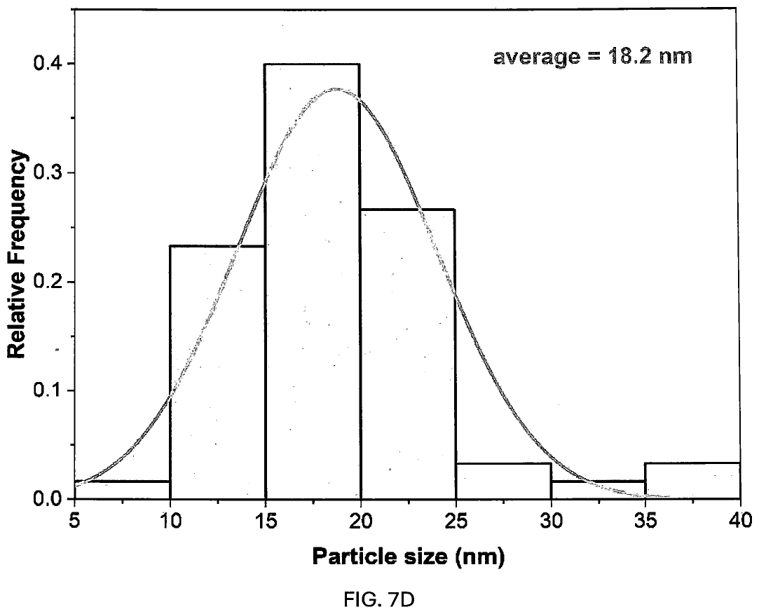

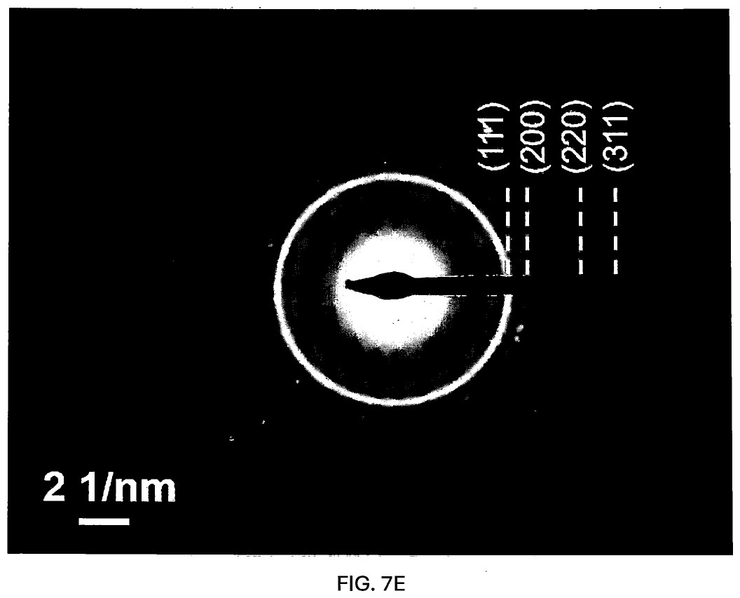

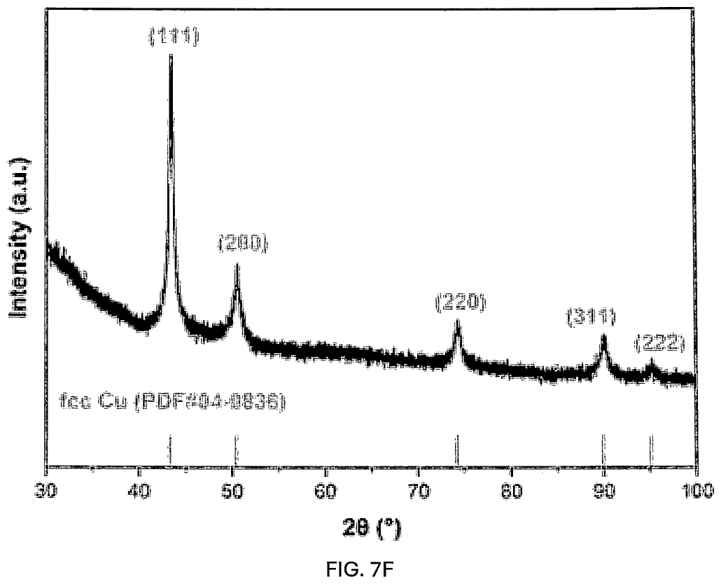

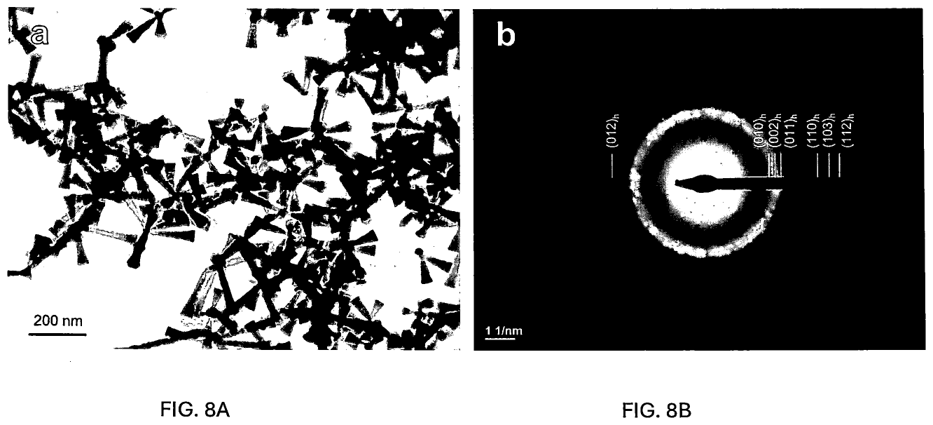

Unconventional phase Cu was obtained through epitaxial growth using hexagonal close-packed (hcp) IrNi nanobranches as the templates in oil phase, and 1,2-butanediol was utilized as the reductant (FIG. 1A, and see more details in below from Materials and Methods section). By controlling the reaction time, the surface distribution of unconventional phase Cu was greatly altered, and the obtained samples were denoted as IrNiCu@Cu-20, IrNiCu@Cu-30 and IrNiCu@Cu-50 based on different reaction times of 20, 30 and 50 mins, respectively. To uncover the difference between common and unconventional phase of Cu, Cu nanoparticles (Cu NPs) with pure fcc phase were also prepared with an average diameter of 18.2 nm (FIGS. 7A-7E). IrNiCu@Cu-20 displays similar morphology as pristine hcp IrNi (FIG. 1B and FIGS. 8A-8B, while the surface of nanobranches becomes rougher (FIG. 1C), which indicates the overgrowth of Cu. The enlarged high-angle annular dark-field scanning transmission electron microscope (HAADF-STEM) image shows obvious twisty surface, and areas with low Z-contrast, which suggests the existence of Cu due to its smaller atomic number (FIG. 1D). The surface and core of IrNiCu@Cu-20 nanobranches display clear hcp diffraction patterns (FIGS. 7E-7F). Besides, the interplanar spacings of 2.17 and 2.31 Å are assigned to the (002)ₕ and (010)ₕ facets of hep phase, respectively (FIG. 7G), and the observation of atoms in low Z-contrast indicates the formation of few-layer 2H Cu nanostructures. The elemental mappings show that unconventional phase Cu nano-islands are uniformly dispersed on the surface nanobranches (FIG. 1H), and the corresponding line scan reveals the Cu/Ir-rich shell and Ni-rich core (FIG. 1I).

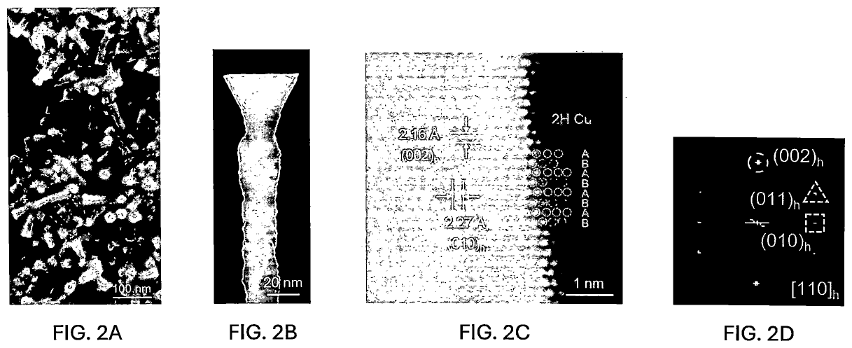

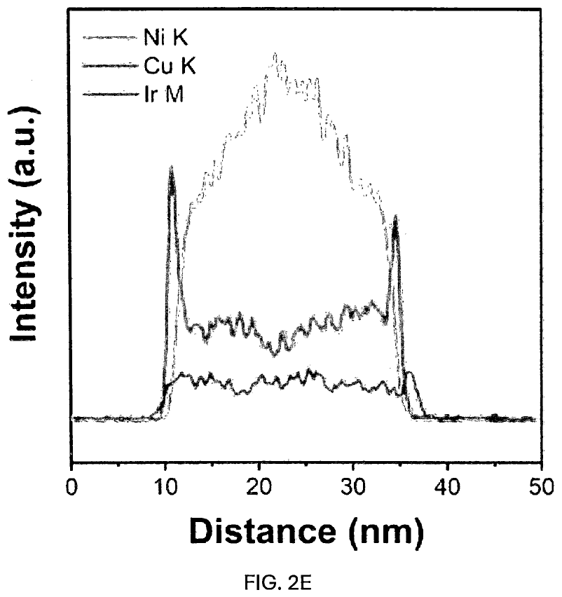

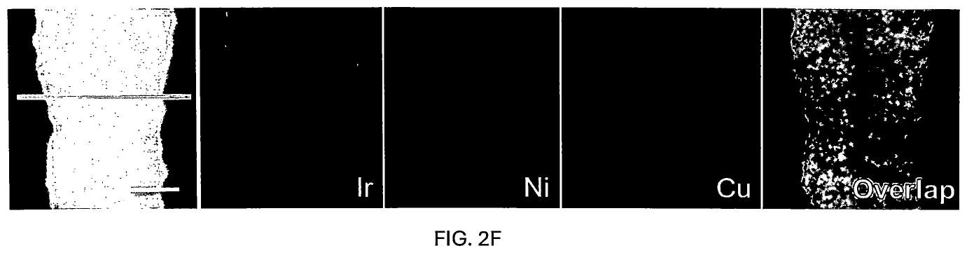

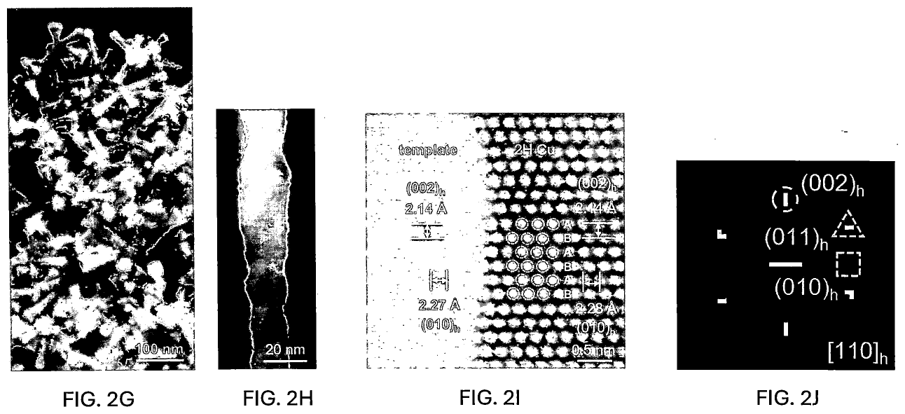

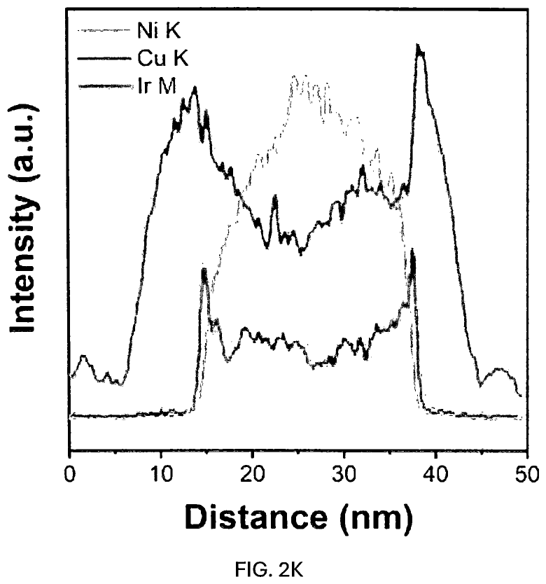

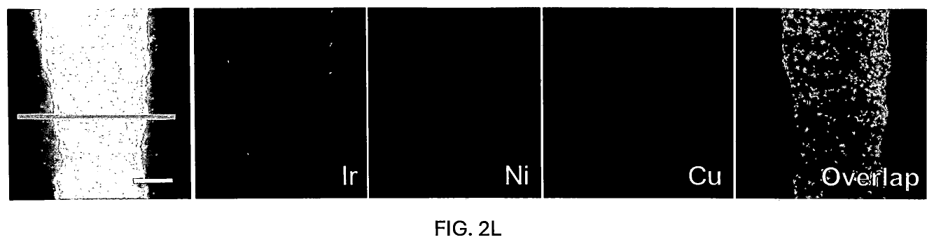

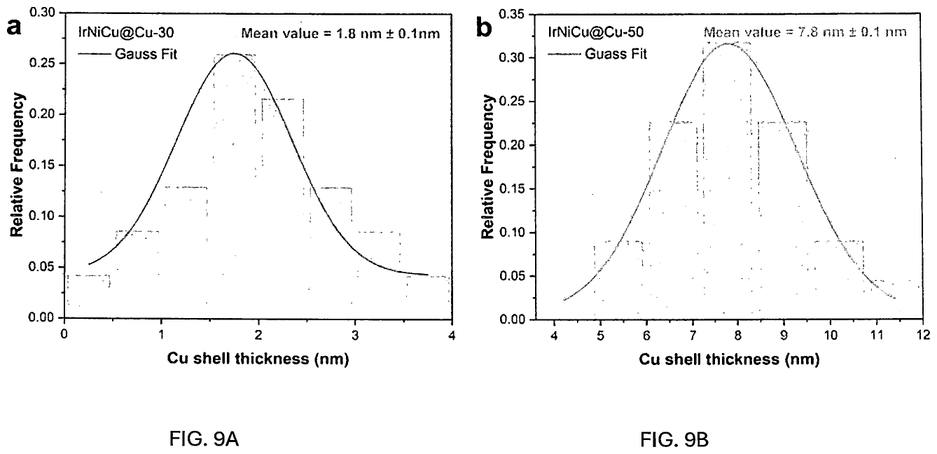

As the reaction time increases to 30 mins, no nanoparticles are observed (FIG. 2A), while the surface of nanobranches becomes more uneven (FIG. 2B). A thin unconventional phase 2H Cu shell is found on IrNiCu@Cu-30 sample as indicated by HAADF-STEM image and the corresponding fast Fourier transform (FFT) pattern (FIGS. 2C-2D). Moreover, the thickness of 2H Cu increases to over four atomic layers, and it inherits “AB” stacking sequence from the template (FIG. 2C). IrNiCu@Cu-30 displays similar line scan profiles as IrNiCu@Cu-20, but the intensity of Cu increases (FIG. 2E), and the thin Cu shell is well characterized by elemental mappings (FIG. 2F). When the reaction time prolongs further to 50 mins, a thick Cu shell appears and encapsulates the template completely, without the formation of Cu nanoparticles (FIGS. 2G-2H). As can be seen from FIG. 2I, Cu atoms follow the atomic arrangement of template, and the atomic-resolved image exhibits the characteristic stacking sequence of “AB” proved by the corresponding selected-area FFT pattern along the [100]ₕ zone axis, (FIG. 2J). In addition, the interplanar spacings of 2.14 and 2.28 Å are ascribed to the (002)ₕ and (010)ₕ facets of 2H Cu, respectively, which are quite close to the corresponding interplanar spacings of template. As can be seen in FIG. 2k, the intensity of Cu K-edge increases markedly, and Cu shell gradually forms with increasing growth time. Specifically, the thickness of Cu shell evolved from 1.8±0.1 nm for IrNiCu@Cu-30 to 7.8±0.1 nm for IrNiCu@Cu-50 (FIGS. 9A-9B, Supporting Information). Based on elemental mappings, IrNiCu@Cu-50 demonstrates a sandwich-like structure, consisting of Ni-rich core, Ir-rich middle layer, and Cu shell (FIG. 2I). Therefore, unconventional phase Cu was successfully obtained and its distribution on the template can be well adjusted.

### X-Ray Spectral Analysis

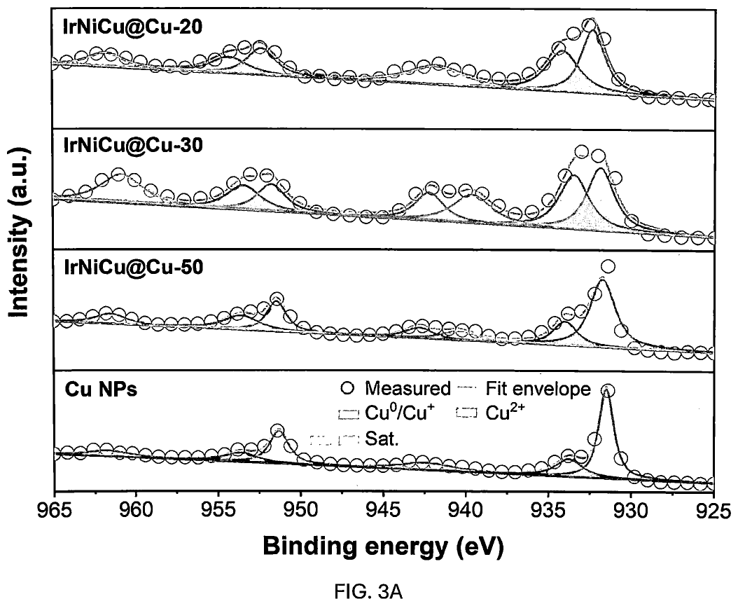

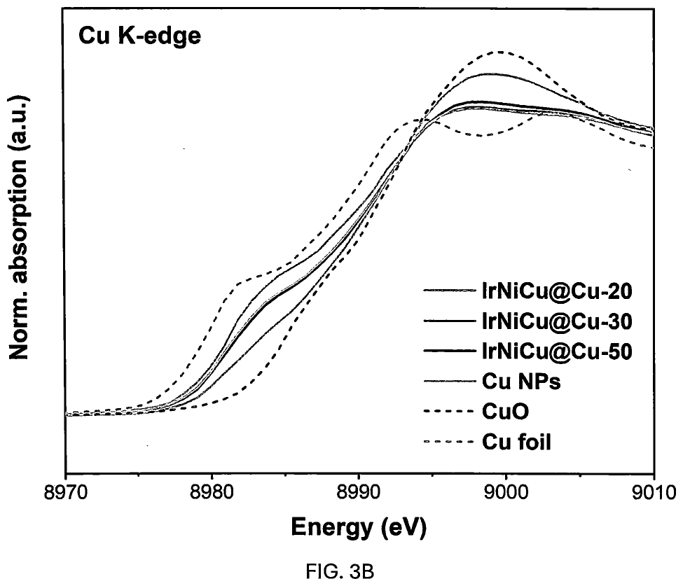

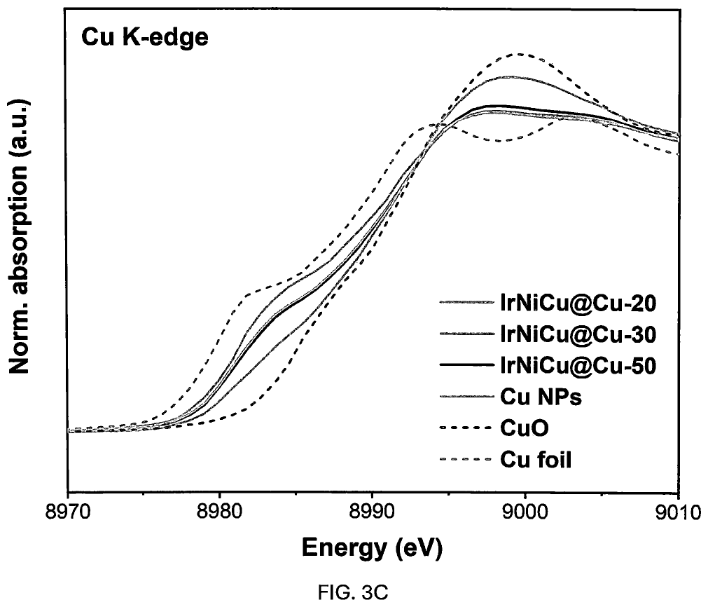

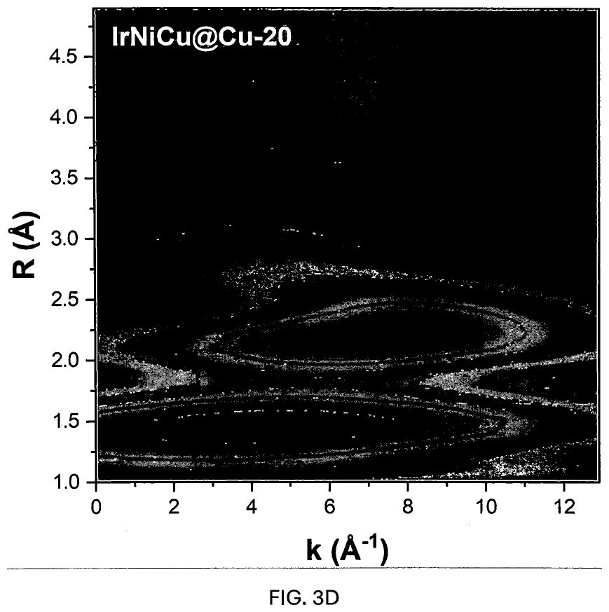

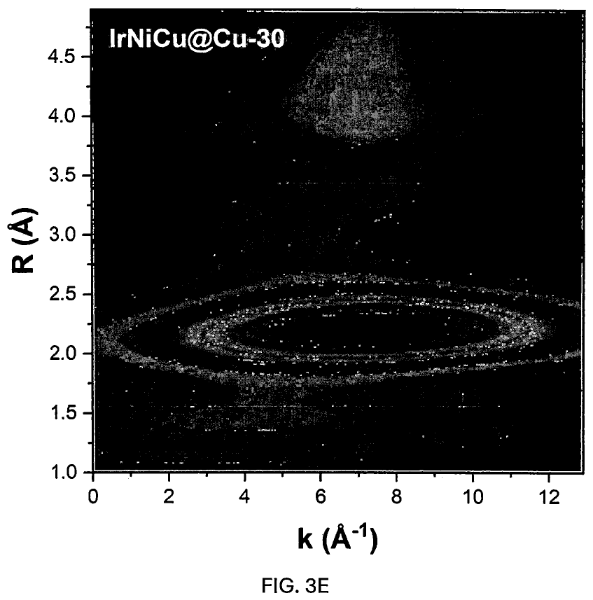

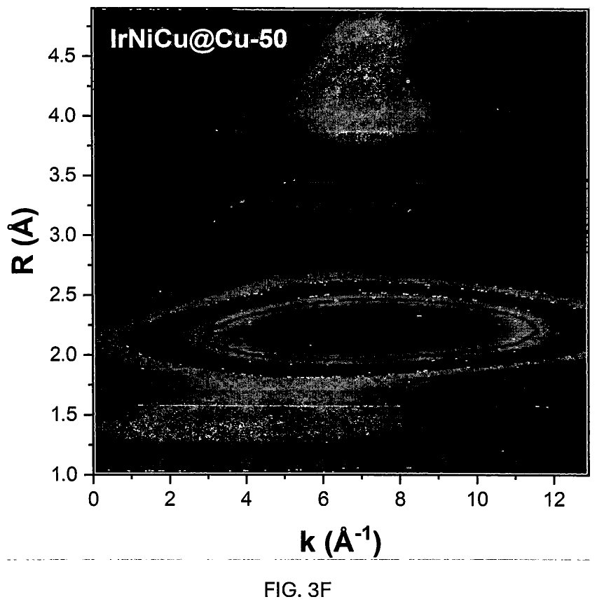

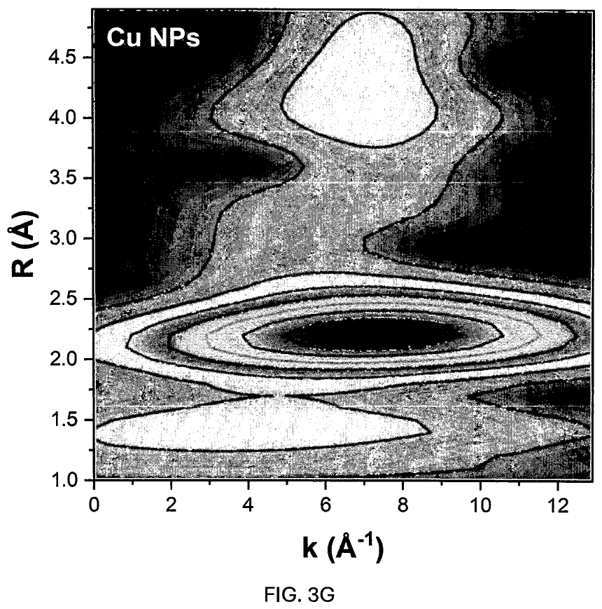

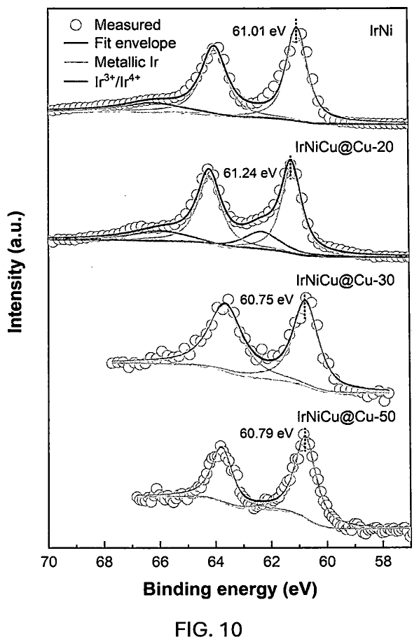

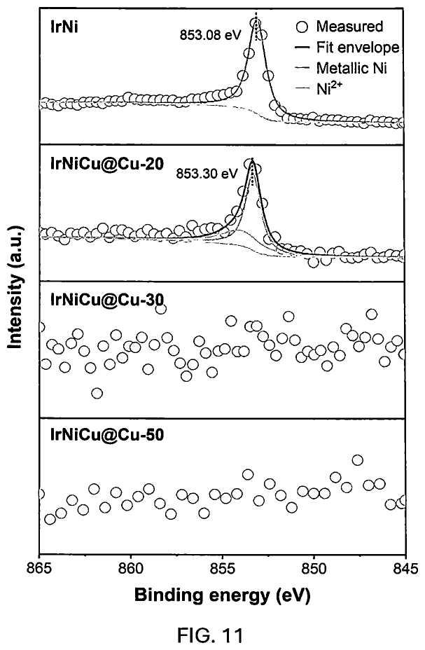

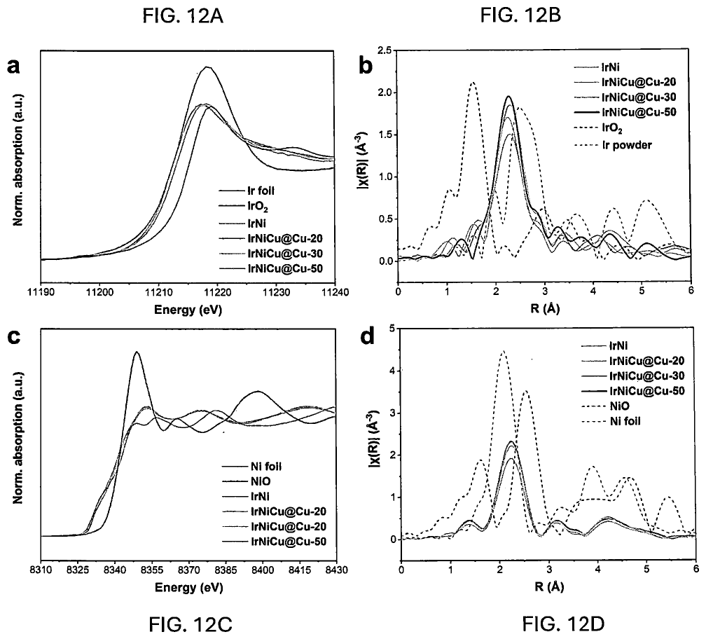

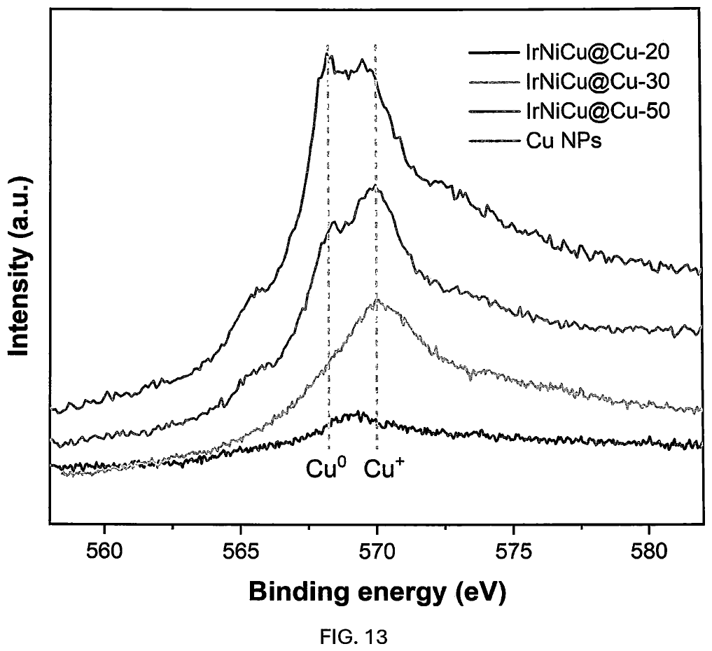

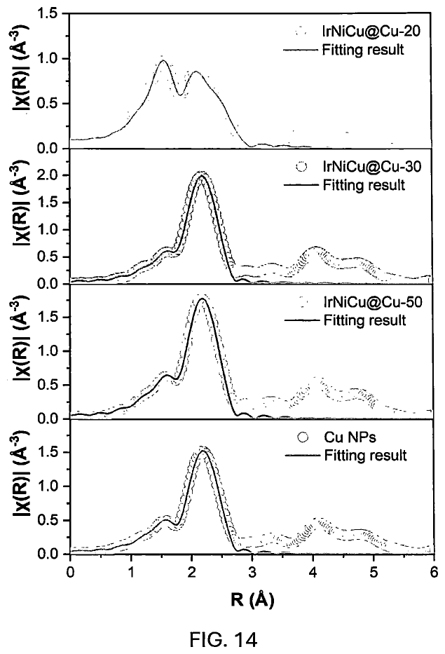

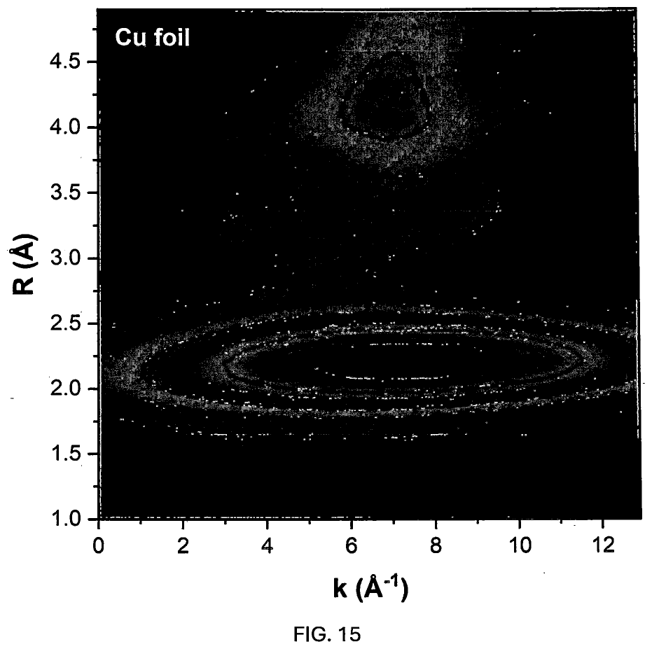

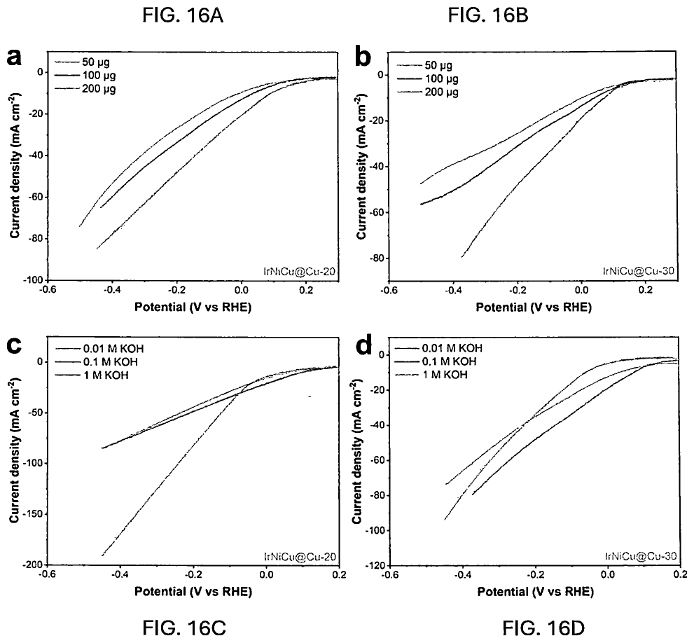

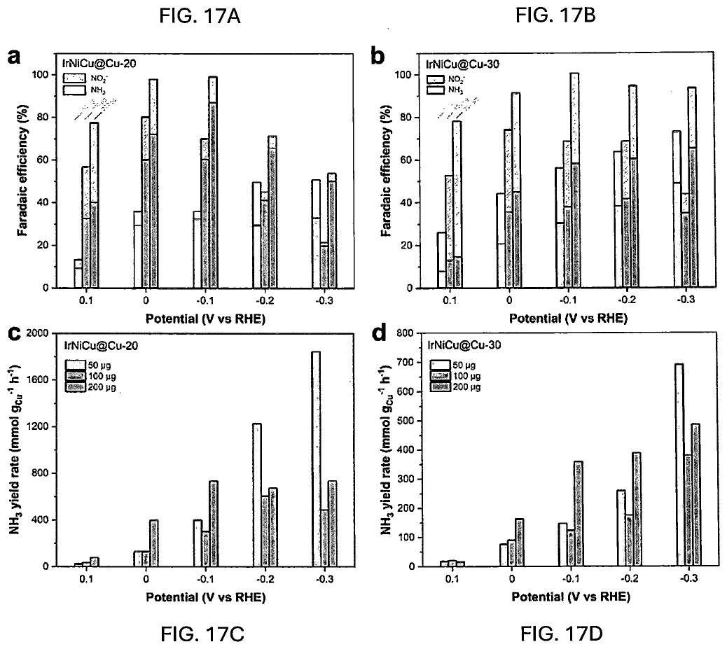

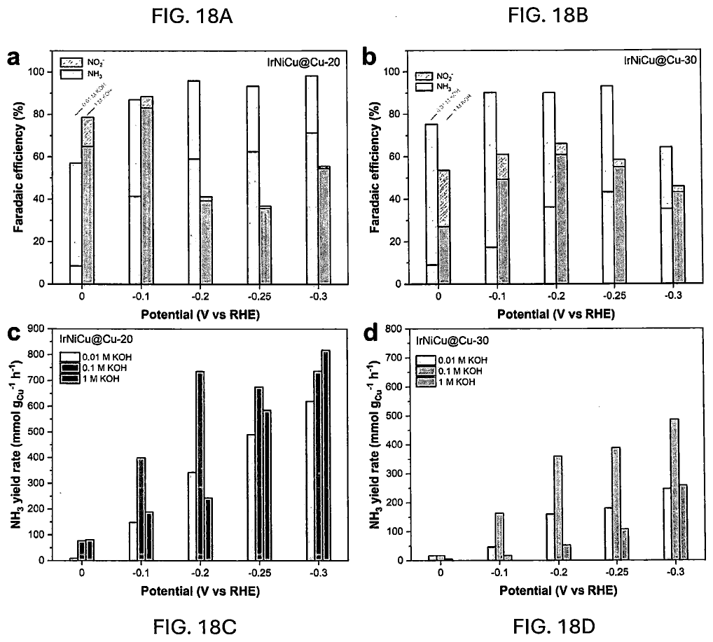

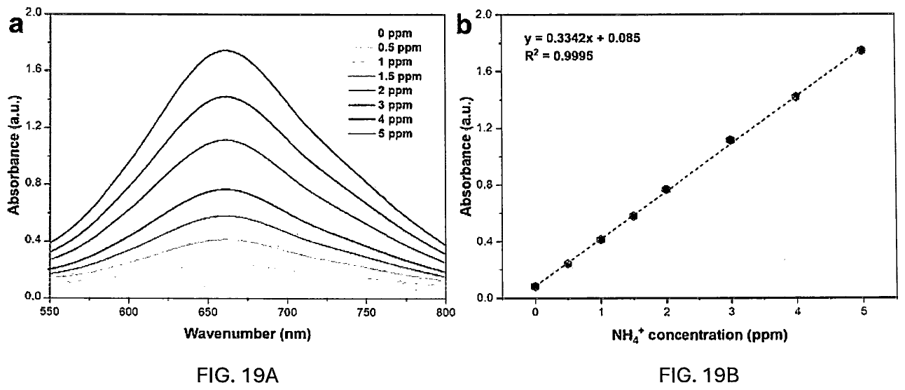

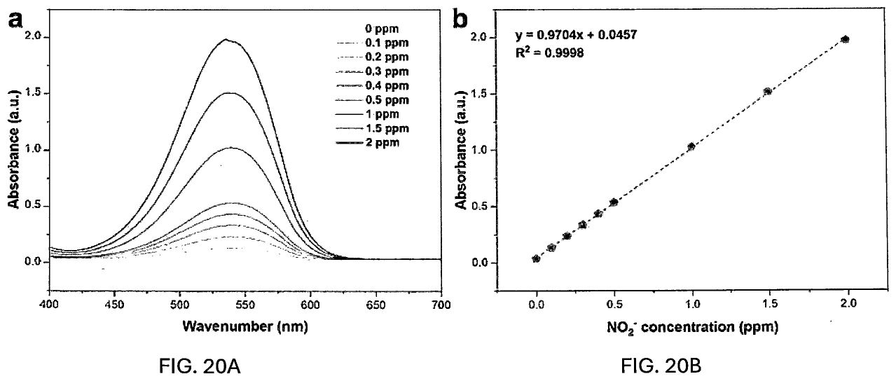

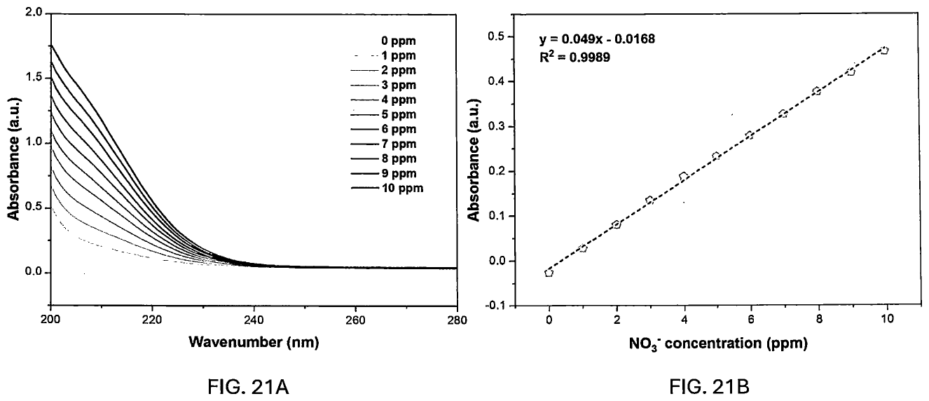

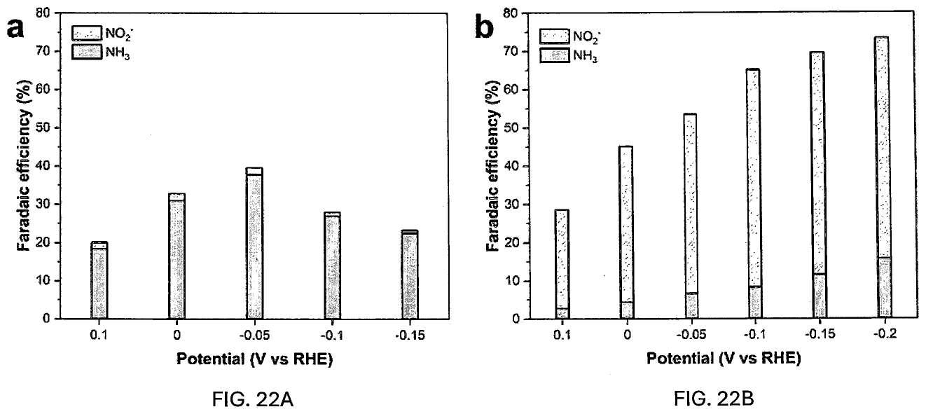

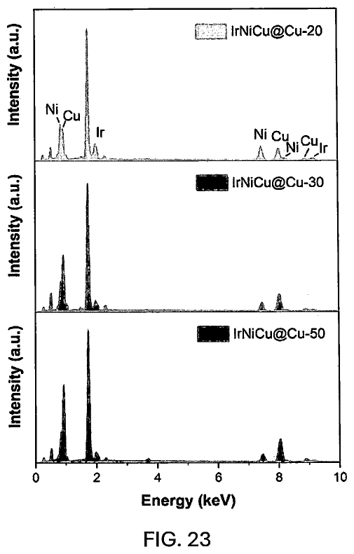

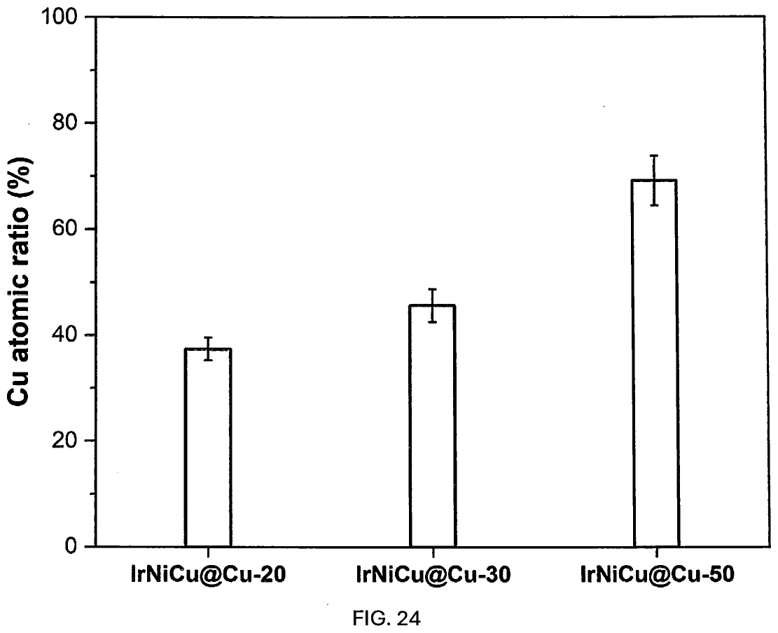

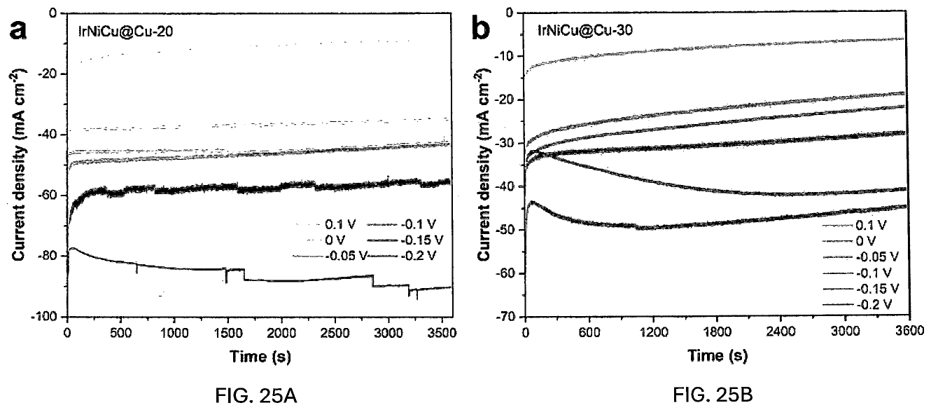

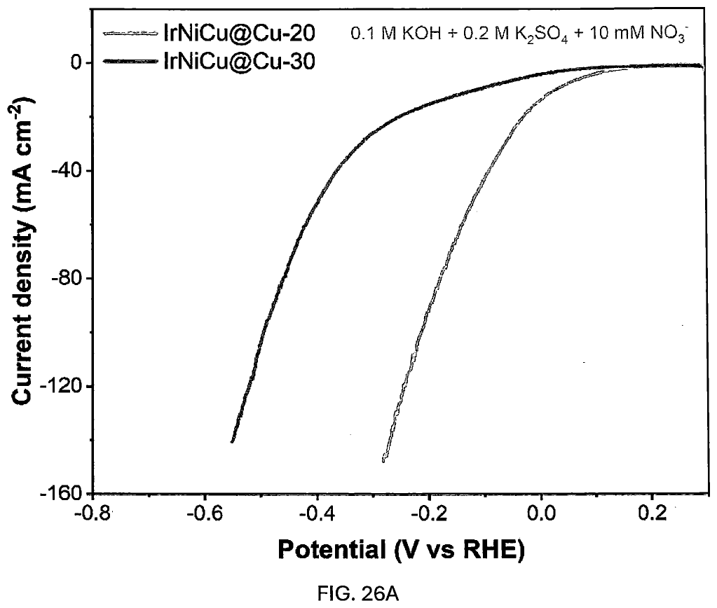

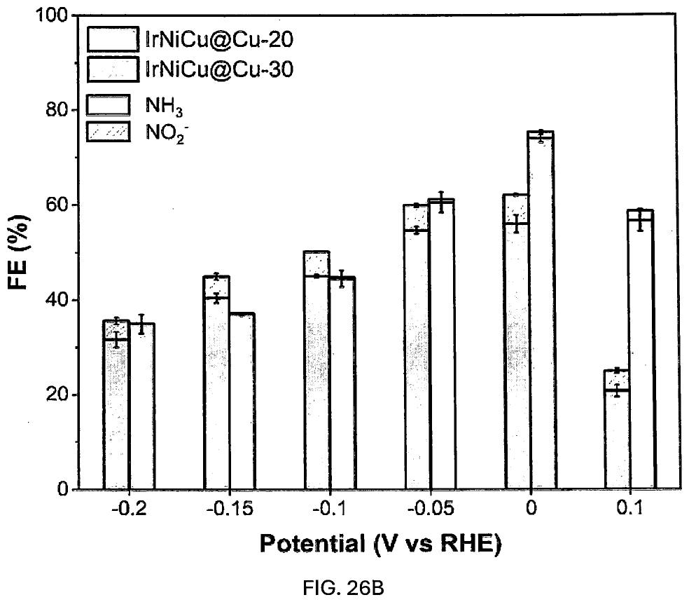

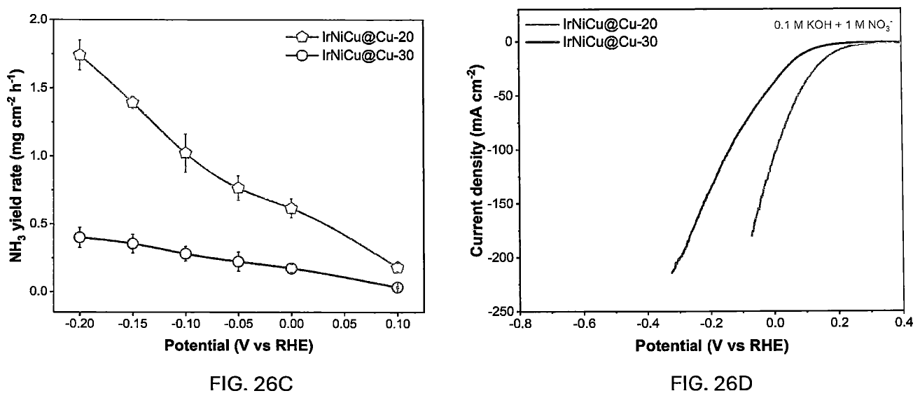

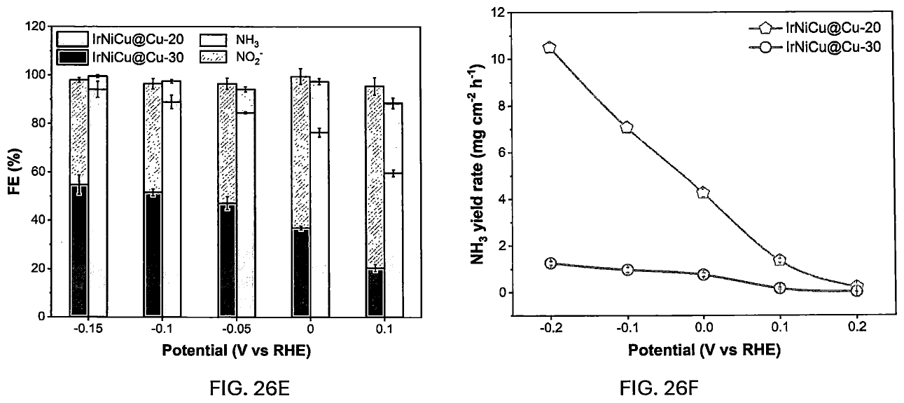

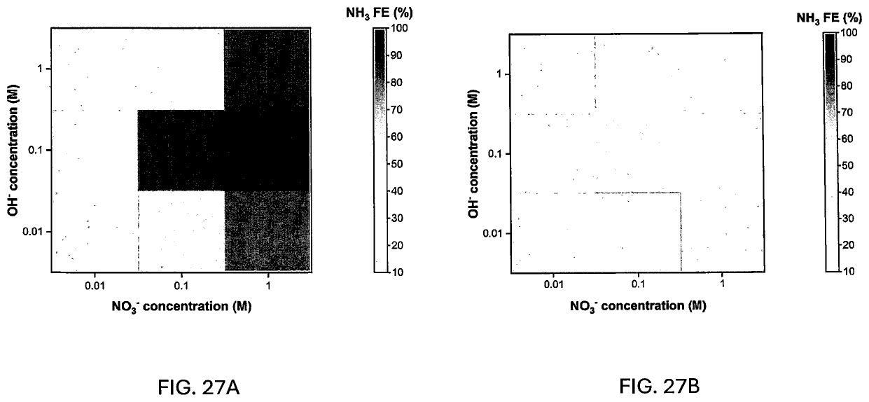

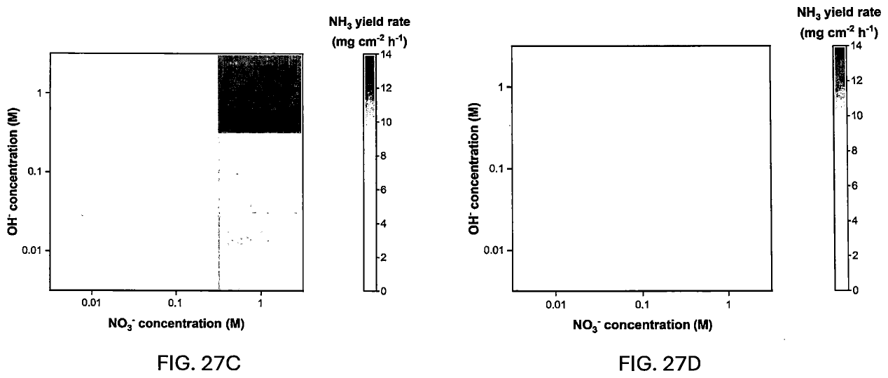

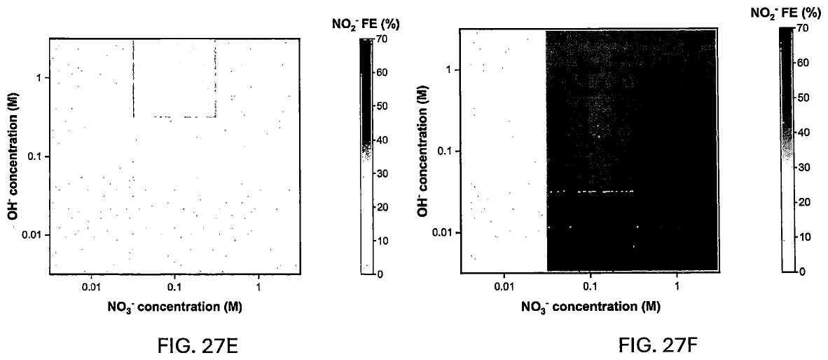

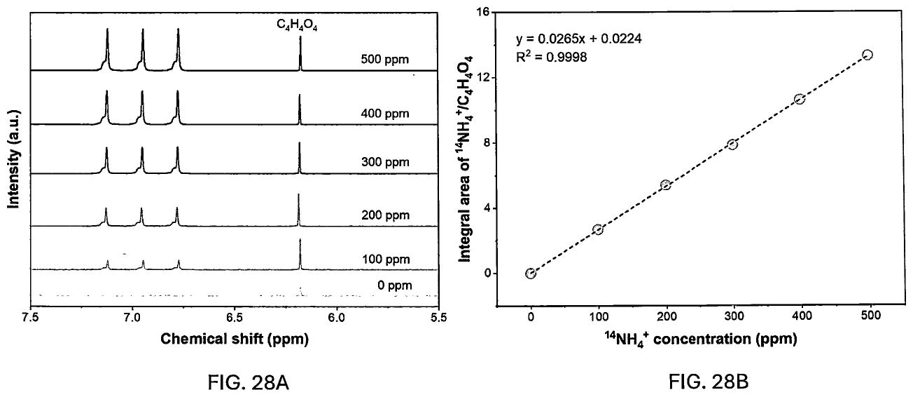

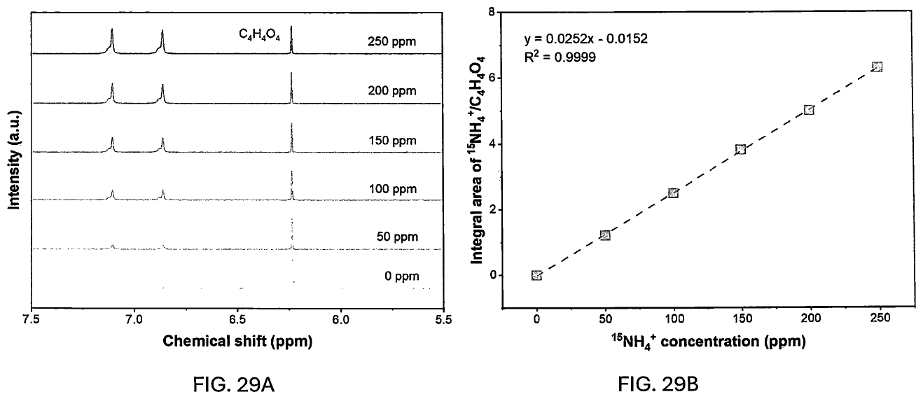

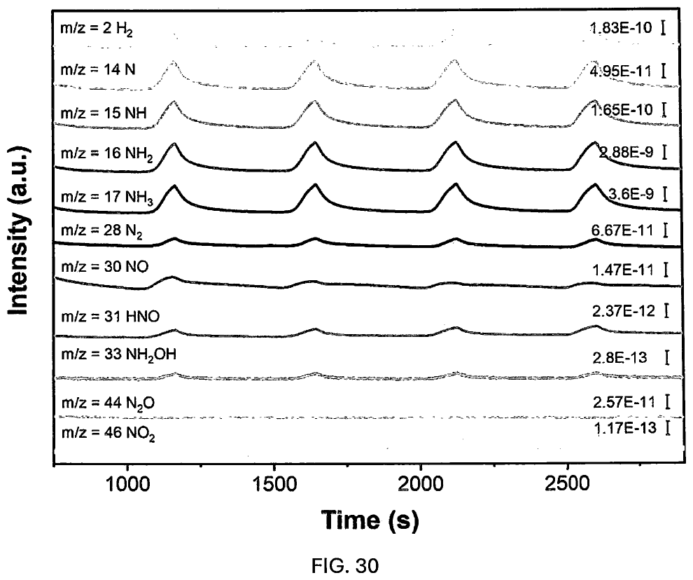

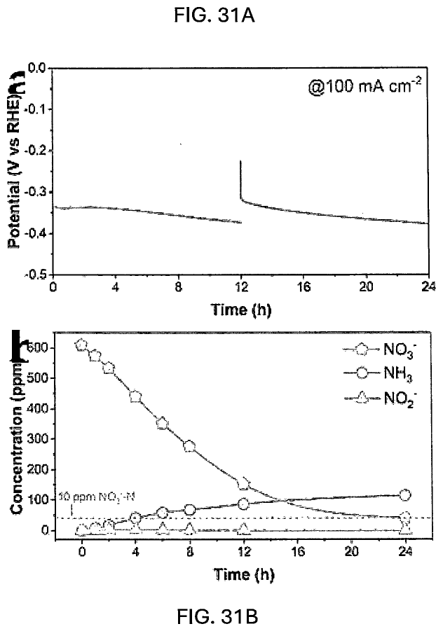

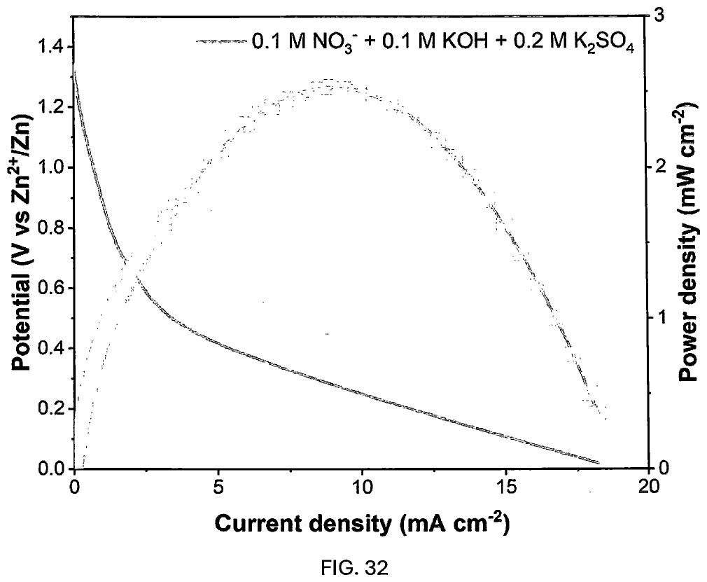

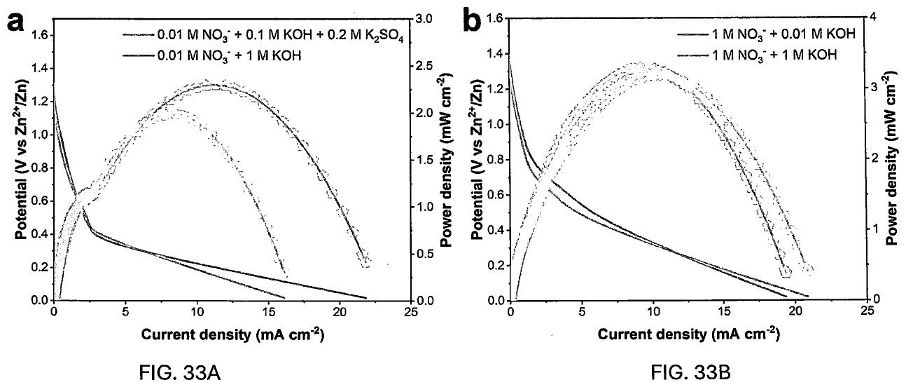

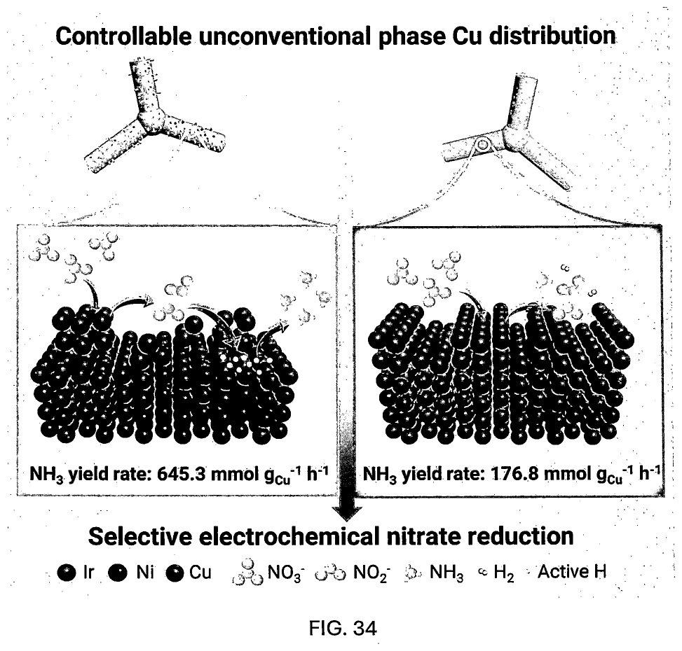

The chemical state and coordination environment of IrNiCu@Cu nanostructures were analyzed by using X-ray photoelectron spectroscopy (XPS) and X-ray absorption spectroscopy (XAS). Ir 4f XPS spectra mainly show metallic Ir peaks at around 61 eV (FIG. 410, Supporting Information), while the Ni 2p XPS spectra can only be detected in IrNiCu@Cu-20 with a metallic Ni peak at about 853.3 eV (FIG. 1I), probably arising from the signal shield by thick atomic layer of Ir and Cu in IrNiCu@Cu-30 and IrNiCu@Cu-50. Notwithstanding, Ni mainly exists in metallic state for these samples, proved by normalized Ni K-edge X-ray absorption near-edge structures (XANES) spectra (FIGS. 12A-12D). In addition, the bond lengths of Ir—Ir and Ni—Ni are quite different from Ir and Ni foils with conventional fcc phase (FIGS. 2A-12D and Table 1). According to Cu 2p XPS spectra, the peaks located at around 931.8 and 951.5 eV represent the 2p3/2 and 2p1/2 doublets of metallic Cu, respectively. Apparently, oxidized Cu species are observed in all samples, especially for IrNiCu@Cu-20 and IrNiCu@Cu-30 with lower Cu contents (FIG. 3A). The Cu LMM Auger electron spectroscopy (AES) spectra further reveal that the proportion of metallic Cu is lower in IrNiCu@Cu-20 and IrNiCu@Cu-30 (FIGS. 7A-7F), while the peak intensities for both Cu⁰ (568 eV) and Cu⁺ (570.3 eV) are comparable for IrNiCu@Cu-50. As can been seen from Cu K-edge XANES spectra, the oxidation state of Cu is between 0 and +2 (FIG. 3B). The lower the amount of Cu, the higher the oxidation state. Based on the corresponding Fourier transformed (FT) k²-weighted extended X-ray absorption fine structure (EXAFS) spectra and fitting results (FIG. 3C, FIGS. 14A-14 and Table 1), all samples display two dominant peaks located at around 2.54 and 1.92 Å, which are ascribed to the Cu—Cu and Cu—O scattering paths of the first shell, respectively. Besides, the coordination number (CN) of Cu—O bond in IrNiCu@Cu-20 is 2.3, higher than that of IrNiCu@Cu-30 (1.1) and IrNiCu@Cu-50 (1.4). Moreover, the wavelet transform (WT) of Cu EXAFS oscillations present a strong Cu—O center in IrNiCu@Cu-20 (FIGS. 3D-3G and FIG. 15), and the relatively high oxidation degree might construct a coordination environment suitable for multi-step nitrate reduction.

### Electrochemical Nitrate Reduction Performance

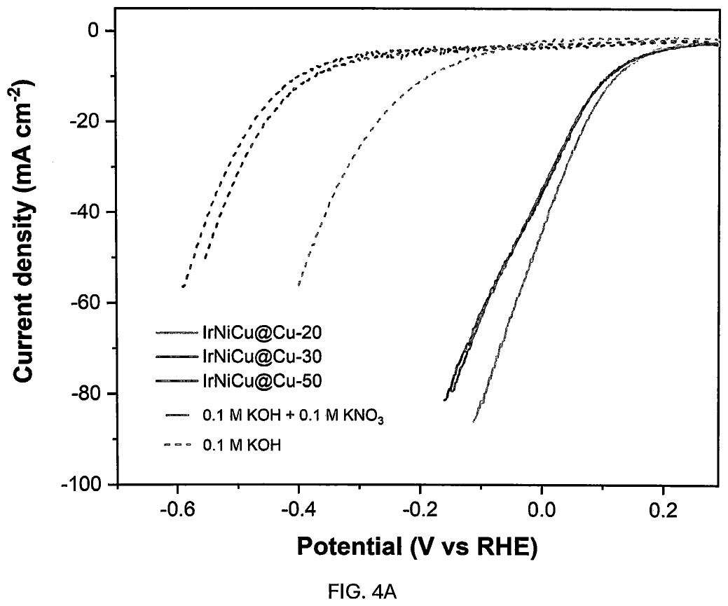

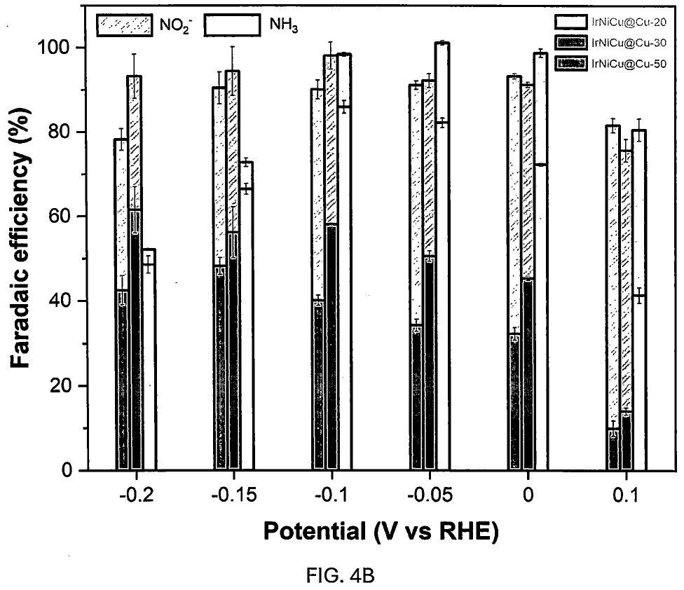

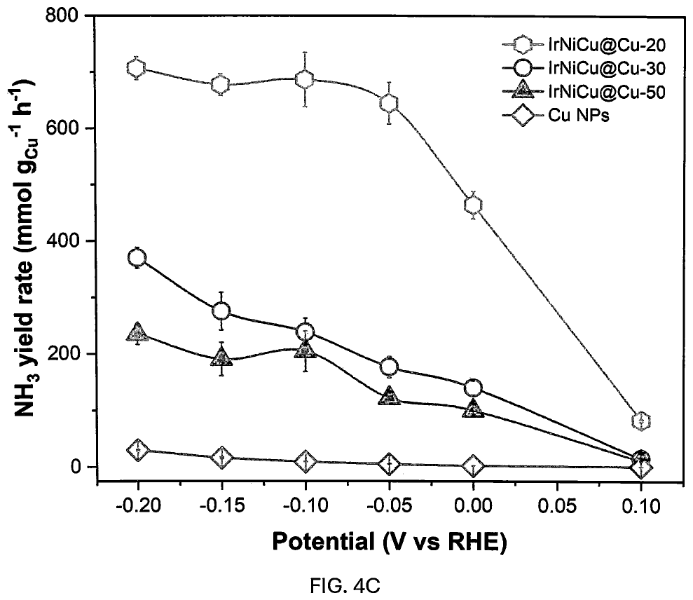

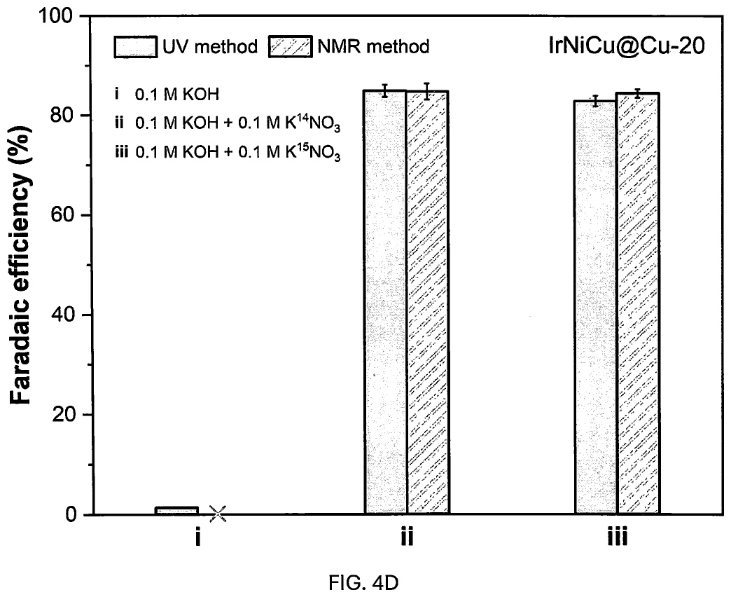

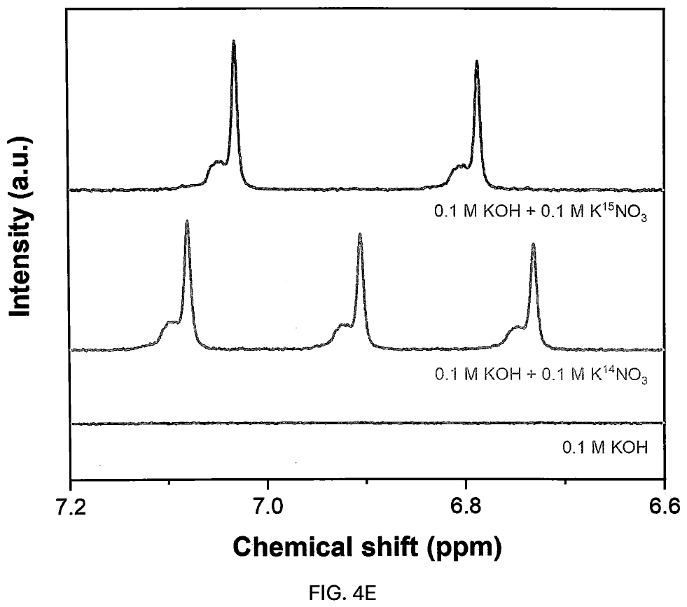

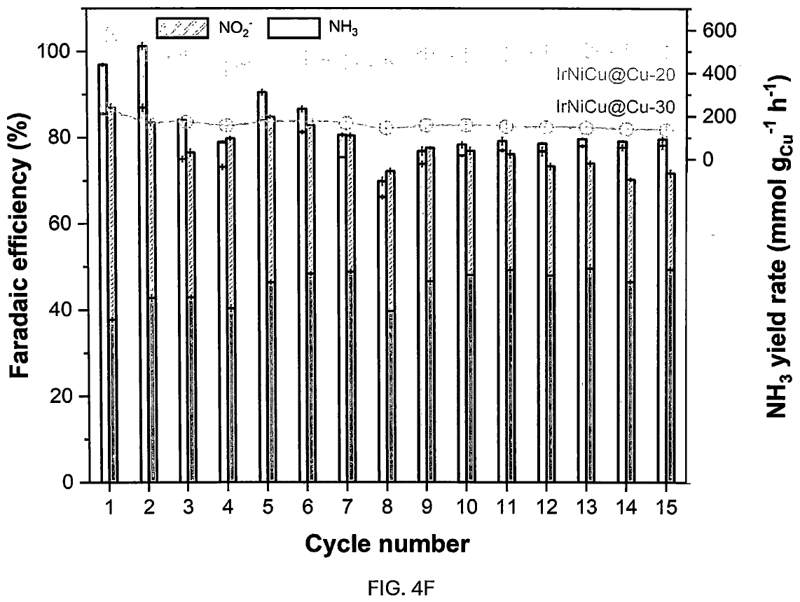

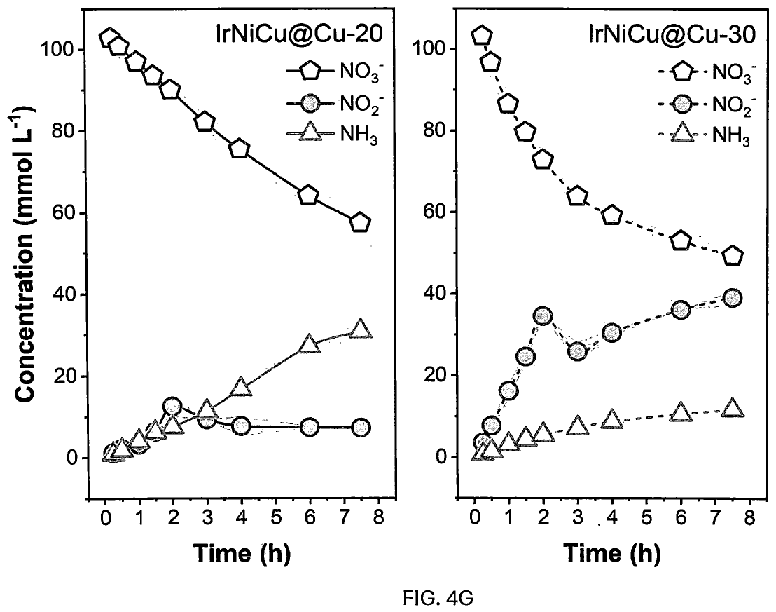

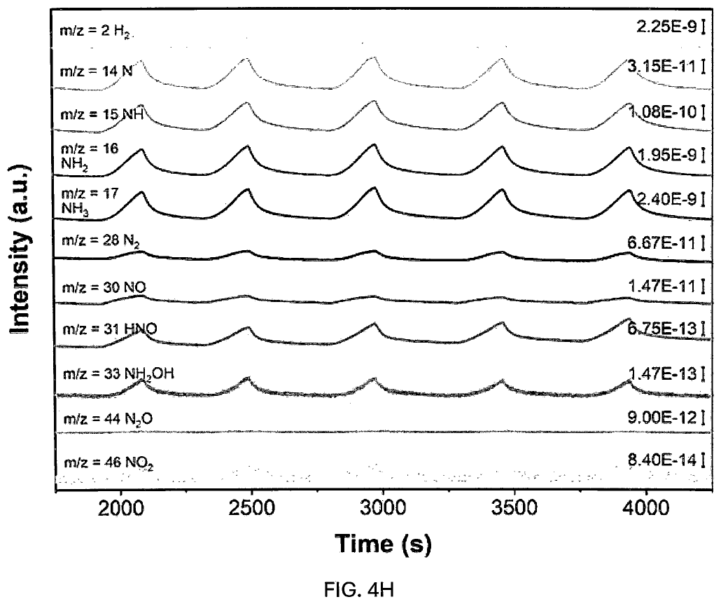

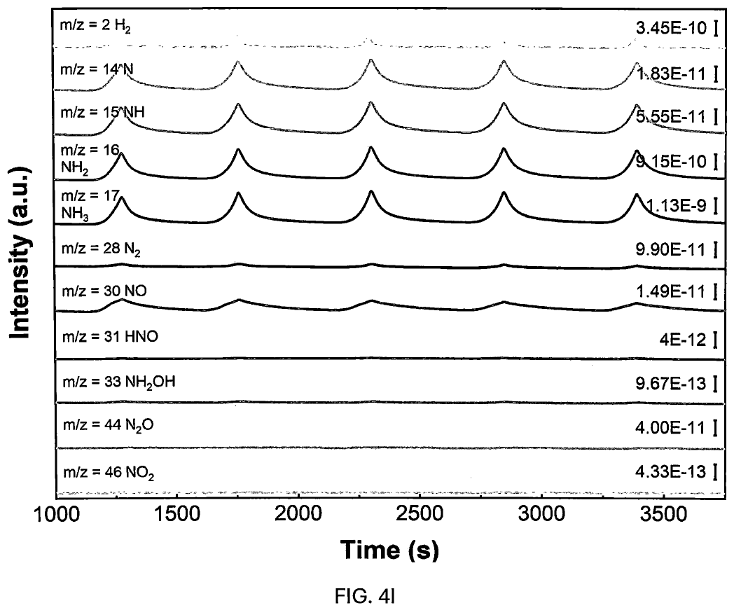

The NO₃RR performance of IrNiCu@Cu nanostructures was evaluated by H-type cell in alkaline electrolyte, and the optimum Cu mass loading was determined to be 200 μg (FIGS. 16A-16D and 17A-17D). Besides, the pH effect was also checked, and 0.1 M KOH is more suitable to obtain optimized NH₃ FE and yield rate as it can suppress hydrogen evolution and offer adequate adsorbed hydrogen (FIGS. 16A-16D and 18A-18D). After adding nitrate into 0.1 M KOH, the current density increases markedly based on linear sweep voltammetry (LSV) curves, and IrNiCu@Cu-20 presents the highest activity towards nitrate reduction with the onset potential of ca. 0.2 V (vs RHE), implying a relatively low overpotential and high energy efficiency (FIG. 4A). Besides, the overpotential decreases by about 366 mV at −40 mA cm⁻², indicating that IrNiCu@Cu-20 favors nitrate reduction other than HER at relevant potentials. The products (mainly NO₂_{^{−}} and NH₃) after potentiostatic electrolysis at several electrode potentials were analyzed by colorimetric methods based on calibration curves (FIGS. 19A-21B. Obviously, IrNiCu@Cu with different unconventional phase Cu distributions demonstrate distinct NO₃RR performance. IrNiCu@Cu-20 shows higher NH₃ FE, while the other two counterparts hold higher NO₂_{^{−}} FE. At 0 V (vs RHE), the total FE of IrNiCu@Cu-20 reaches up to 98.8%, and the highest NH₃ FE of 86% is obtained at −0.1 V (vs RHE) (FIG. 4B). Then, the total FE drops at more negative potentials due to the competitive HER. In contrast, IrNiCu@Cu-30 presents the highest NO₂_{^{−}} FE of 61.8% at 0.1 V (vs RHE), and NO₂_{^{−}} FE gradually decreases with decreasing potentials. IrNiCu@Cu-50 follows the same trend as IrNiCu@Cu-30 as the surface of both catalysts is mostly covered by Cu, and the pure fcc Cu generates NO₂_{^{−}} as the primary product with a high NO₂_{^{−}} FE of 58% at −0.15 V (vs RHE) (FIGS. 22A-22B).

Considering the poor NO₃RR performance of pristine IrNi template (FIGS. 21A-21B, NH₃ yield rate was calculated based on the mass loading of Cu, and the atomic ratio of Cu was confirmed by both energy dispersive X-ray spectroscopy (EDS) (FIGS. 23 and 24). IrNiCu@Cu-20 exhibits significantly faster NH₃ generation rate, with the maximum value of 687.3 mmol g_{Cu}⁻¹ h⁻¹ (FIG. 4C). However, the highest NH₃ yield rates of IrNiCu@Cu-30 and IrNiCu@Cu-50 are 370.3 and 235.1 mmol g_{Cu}⁻¹ h⁻¹, respectively, and the value for fcc Cu NPs is almost negligible. Correspondingly, IrNiCu@Cu-20 presents higher current density at the same electrode potential during electrolysis (FIGS. 25A-25B). This indicates that the utilization rate of Cu atoms becomes lower in the occasion of thick Cu aggregation, and manipulating the configuration of unconventional phase Cu is effective in regulating NO₃RR performance. Afterward, the effect of NO₃_{^{−}} level was investigated, and IrNiCu@Cu-20 performs better than IrNiCu@Cu-30 in both 0.01 M and 1 M NO₃_{^{−}}. 1 M NO₃_{^{−}} brings greater current density, and a higher NHs yield rate of 2233.61 mmol g_{Cu}⁻¹ h⁻¹ at −0.2 V (vs RHE) was achieved for IrNiCu@Cu-20 (FIGS. 26-26F). By integrating the performance data acquired in different media, heatmaps of NH₃ FE, NH₃ yield rate and NO₂_{^{−}} FE over IrNiCu@Cu-20 and IrNiCu@Cu-30 were constructed (FIGS. 27A-27F). Generally, NO₃_{^{−}} level is a key factor, while OH⁻ concentration is not a significant performance enhancer. At relatively high NO₃_{^{−}} level, the hydrogenation rate might not keep up with the NO₃_{^{−}}-to-NO₂_{^{−}} conversion rate for IrNiCu@Cu-30 with a higher surface Cu coverage, thus leading to NO₂_{^{−}} accumulation. For IrNiCu@Cu-20, more exposed Ir atoms provide enough active sites to convert NO₂_{^{−}} to NH₃. Simply put, the distribution of unconventional phase Cu affects the reaction endpoint by controlling the hydrogenation rate. In addition, IrNiCu@Cu-20 shows a competitive electrochemical nitrate-to-ammonia performance in alkaline media with low overpotential compared to other reported catalysts (Table 2).

To confirm the accuracy of NH₃ quantification, 1H nuclear magnetic resonance (NMR) spectroscopy was applied to check the concentration of NH₄_{⁺} (FIGS. 28A-28B and 29A-29B). The FEs determined by colorimetric tests and NMR tests are comparable using K¹⁴NO₃ or K¹⁵NO₃ as nitrate sources, and trace amount of NH₃/NH₄_{⁺} is produced under electrolysis without nitrate (FIG. 4D). In addition, ¹H NMR spectra using ¹⁴KNO₃ as the electrolyte showed the typical triplet of ¹⁴NH₄_{⁺}, whereas the expected double peaks of ¹⁵NH₄_{⁺} were observed in reactions with ¹⁵KNO₃ (FIG. 4E). In addition, no peaks for NH₄_{⁺} showed after electrolysis without nitrate at −0.1 V (vs RHE). Subsequently, the stability of IrNiCu@Cu nanostructures was checked during 15 consecutive cycles (FIG. 4F). IrNiCu@Cu-20 shows around 80% NH₃ FE, and the NH₃ yield rate of IrNiCu@Cu-20 slightly fluctuates at ca. 500 mmol g_{Cu}⁻¹ h⁻¹, always above those of IrNiCu@Cu-30. In comparison, NH₃ FE of IrNiCu@Cu-30 is at the level of 40%, with about 35% FE towards NO₂_{^{−}}. Therefore, it is speculated that the configuration of IrNiCu@Cu-20 is suitable for deep hydrogenation of NO₂_{^{−}} to generate NH₃, as more Ir atoms with the ability to produce active hydrogen can be exposed at the catalytic interface.

Real-time monitoring of N-species (e.g., NO₃_{^{−}}, NO₂_{^{−}}, NH₃) concentration was conducted to reveal the conversion process during nitrate reduction (FIG. 4G). Over a 7.5-h electrolysis period, the removal rate of NO₃_{^{−}} is about 50% using IrNiCu@Cu-20 and IrNiCu@Cu-30 as electrocatalysts. Significantly, the cumulative NO₂_{^{−}} concentration reaches the maxima after 2 h, and then NO₂_{^{−}} will be transformed to NH₃ through a series of proton-coupled electron transfer steps. For IrNiCu@Cu-20, the NH₃ level gradually increases to 30.9 mmol L⁻¹, while the main product for IrNiCu@Cu-30 after NO₃_{^{−}} reduction is apparently NO₂_{^{−}}, with the final NO₂_{^{−}} level of 39.2 mmol L⁻¹. Thus IrNiCu@Cu-20 shows better NO₃_{^{−}}to-NH₃ conversion capability, which is further proved by in-situ differential electrochemical mass spectroscopy (DEMS). NH₃ and its fragments (e.g., N, NH, NH₂) were detected for both IrNiCu@Cu-20 and IrNiCu@Cu-30. Importantly, the signal of nitroxyl (HNO) and hydroxylamine (NH₂OH), as the iconic intermediate on the pathway towards NH₃, is observed for IrNiCu@Cu-20, indicating that hydrogenation reactions occur to form NH₃ (FIG. 4H). However, these intermediates are negligible for IrNiCu@Cu-30 and IrNiCu@Cu-50 (FIG. 4I, and FIG. 30), and a weak peak of NO₂_{^{−}} byproduct is discernable for IrNiCu@Cu-50. Furthermore, IrNiCu@Cu-20 was applied in continuous 24-h electrolysis under constant current density of 0.1 A cm⁻², and the residual NO₃_{^{−}} level dropped below the drinking water standard (10 mg L⁻¹ NO₃_{^{−}}—N) with negligible amount of NO₂_{^{−}} produced (FIGS. 31A-31B). This proves that IrNiCu@Cu-20 is potential in removing and converting NO₃_{^{−}} to NHs toward practical treatments.

### Theoretical Studies

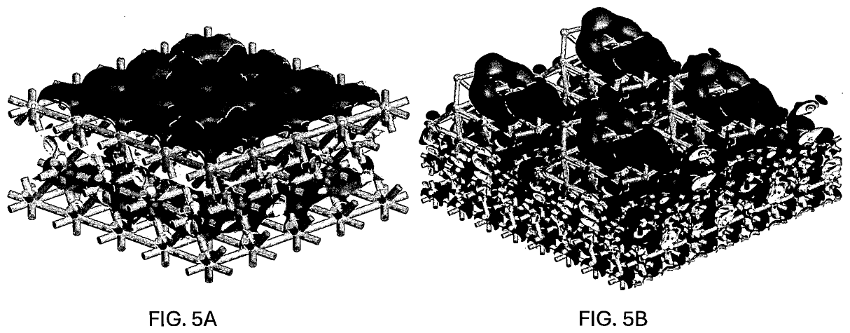

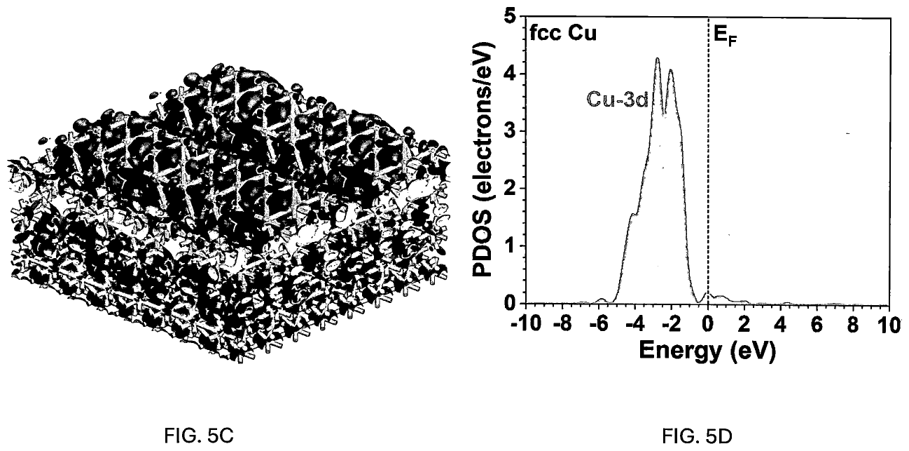

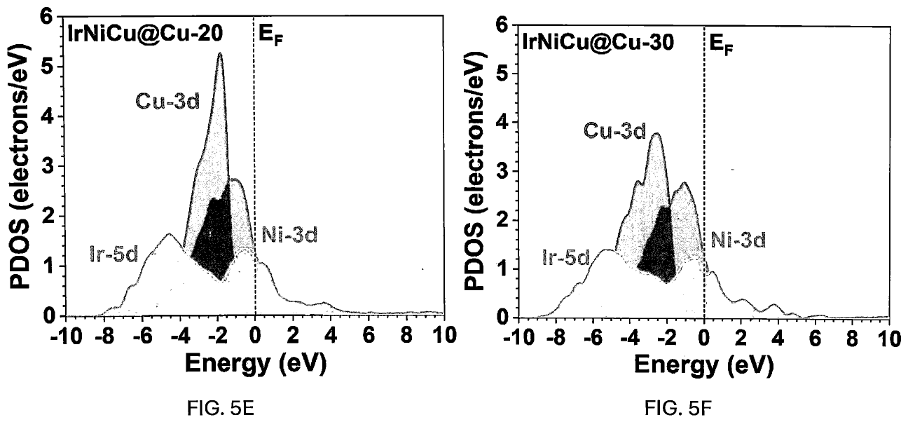

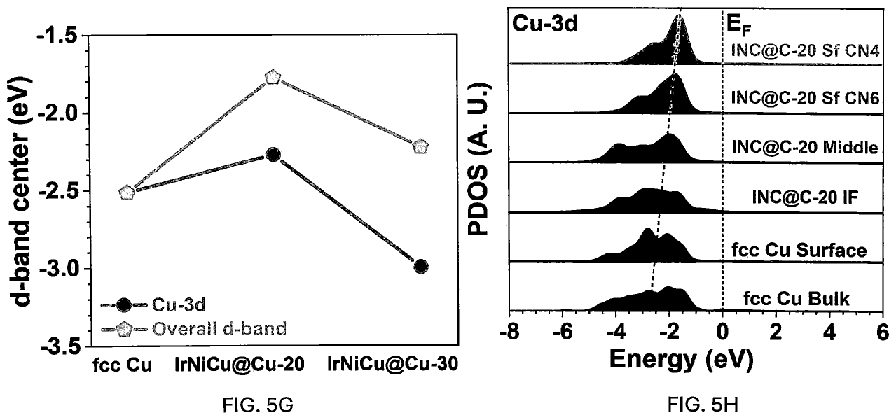

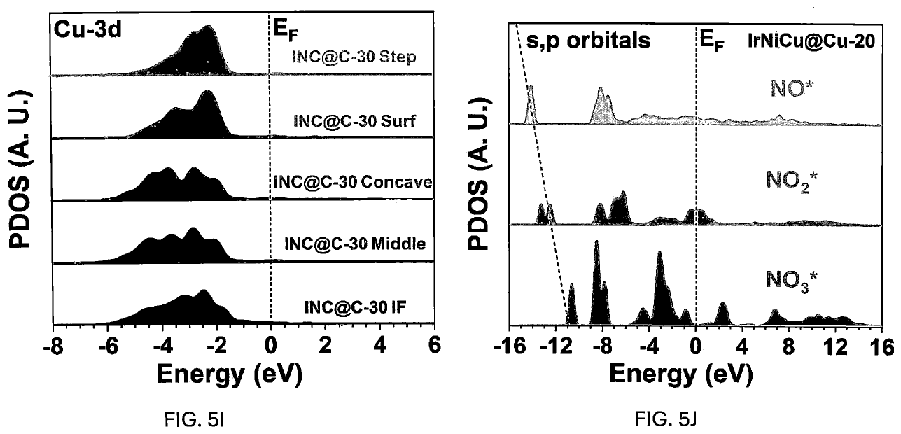

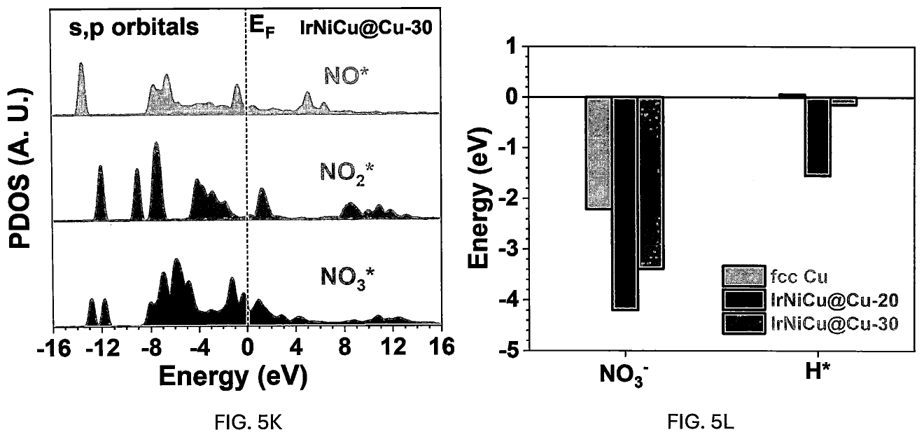

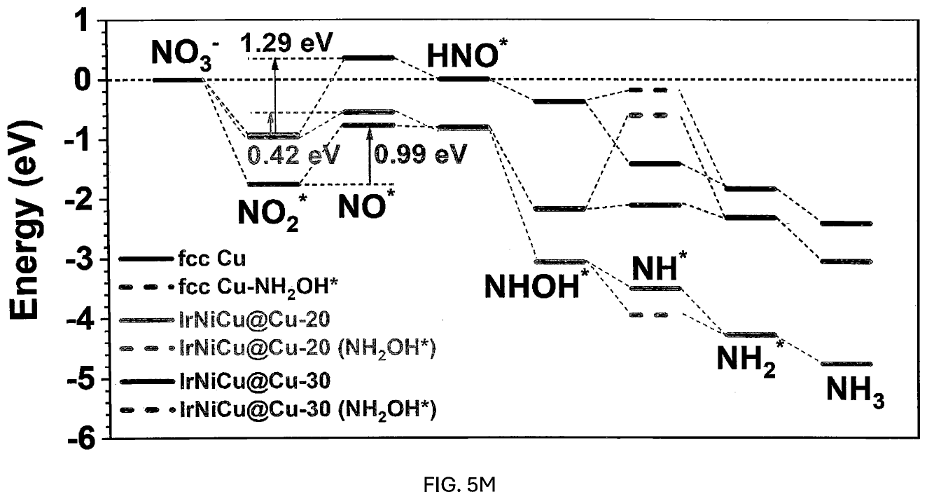

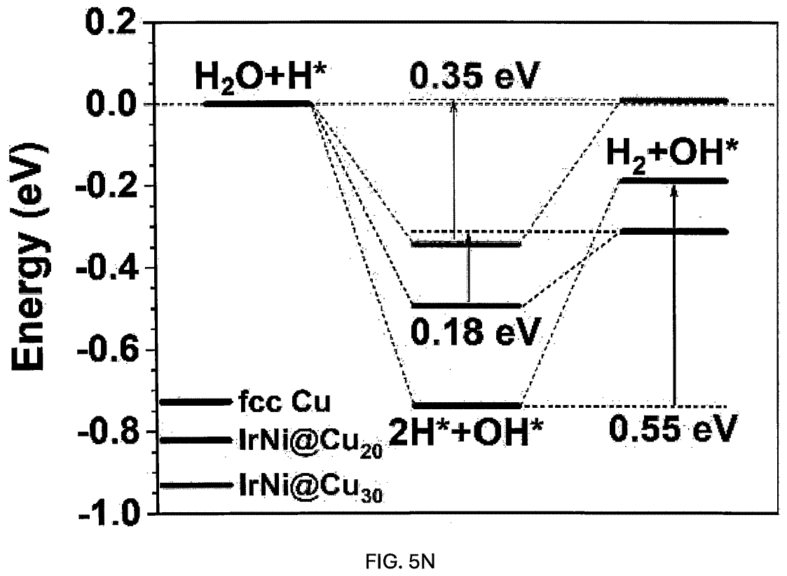

To reveal the origins of high NO₃RR performances of IrNiCu@Cu-20 for the generation of NH₃, DFT calculations have been further carried out to investigate the electronic structures and reaction trends. First of all, the present invention has demonstrated the surface electronic distributions regarding the bonding and anti-bonding orbitals near the Fermi level (E_{F}). For the fcc Cu surfaces, the surface is mainly dominated by the anti-bonding orbitals, indicating the weak capability of electron transfer (FIG. 5A). In contrast, the surface IrNiCu@Cu-20 shows much higher contributions of the bonding orbitals, especially near the edge sites of the surface Cu (FIG. 5B). This reveals that the surface low-coordinated Cu sites are highly electroactive, which contributes to the adsorption of key intermediates with efficient electron transfer. The exposed surface of IrNi surfaces also has strong distributions of bonding orbitals, potentially facilitating the electron transfer to enhance the water dissociation for efficient generation of protons during NO₃RR. As the surface Cu layers further grow in IrNiCu@Cu-30, the electroactivity of the surfaces reduces owing to the decreases of low coordinated sites, where the bonding orbitals are concentrated at the limited edge sites (FIG. 5C). The projected partial density of states (PDOS) of fcc Cu has revealed that Cu-3d orbitals are mainly located between E_{V}-1.0 eV to E_{V}-5.0 eV (E_{V} denotes 0 eV) with low electron density near the E_{F}, indicating the limited electron transfer efficiency (FIG. 5D). For IrNiCu@Cu-20, Cu-3d orbitals display a sharp peak with an upshifted location towards the E_{F}, revealing the evidently improved electroactivity for NO₃RR (FIG. 5G). Both Ir-5d and Ni-3d orbitals have significantly contributed to the largely increased electron density near E_{F}, which not only improves the site-to-site electron transfer efficiency but also reduces the resistance of the IrNiCu@Cu-20, leading to the optimized electroactivity. As the concentration of Cu further increases in IrNiCu@Cu-30, the Cu-3d orbitals have exhibited a downshift, resulting in reduced electroactivity (FIG. 5F). Meanwhile, electronic structures of the IrNi have not been significantly affected, where both the Ir-5d and Ni-3d orbitals remain similar to that in IrNiCu@Cu-20. These results demonstrate that the different electroactivity towards NO₃RR is induced by the electronic structures of surface Cu in IrNiCu@Cu-20 and IrNiCu@Cu-30. Based on the d-band center comparisons, it is noted that IrNiCu@Cu-20 has shown the highest d-band center of Cu and the overall structure, supporting the optimal electroactivity towards the NO₃RR (FIG. 5G). Compared to fcc Cu, the IrNiCu@Cu-30 displays a lower d-band center of Cu sites but a higher overall d-band center than fcc Cu. To explore the electronic structures of Cu sites, we have compared the site-dependent PDOS of Cu-3d orbitals in fcc Cu and IrNiCu@Cu-20 (FIG. 5H). Notably, the Cu-3d orbitals gradually upshift from fcc Cu bulk to the surface of IrNiCu@Cu-20. In particular, the surface Cu sites with low CN have displayed much sharper PDOS than those middle and interface Cu sites with higher coordination, which play as the main active sites to guarantee the efficient NO₃RR. In comparison, the Cu sites in IrNiCu@Cu-30 show overall broadened 3d orbitals and a downshifted position than the IrNiCu@Cu-20 (FIG. 5I). Even for the surface and step Cu sites, the 3d orbitals only slightly upshift towards the Er, leading to the evidently reduced electroactivity than the IrNiCu@Cu-20. For the adsorptions of key intermediates from NO₃* to NO*, the PDOS shows a good linear relationship of the σ orbitals, which guarantees fast electron transfer during the reduction process (FIG. 5J). Such a linear relationship of the PDOS is absent in the IrNiCu@Cu-30, indicating the conversion from NO₂* to NO* potentially meets higher barriers (FIG. 5K). This determines the high yield of NO₂_{^{−}} with the limited generation of NH₃ for the NO₃RR on IrNiCu@Cu-30.

The adsorption energies of NOs and protons are important for the NO₃RR, which are compared among fcc Cu, IrNiCu@Cu-20, and IrNiCu@Cu-30 (FIG. 5L). The adsorption of both NO₃_{_{−}} and H* are most energetically preferred on IrNiCu@Cu-20, benefiting the subsequent reduction of NO₃RR. In addition, the much stronger binding of the proton on IrNiCu@Cu-20 suppresses the unfavored HER process to guarantee a high selectivity and yield of NH₃ generation. For NO₃RR, IrNiCu@Cu-20 has the strongest reaction trend with the smallest energy barrier for NO₃RR, where the conversion from NO₂* to NO* is the rate-determining step (RDS) with an energy barrier of 0.42 eV (FIG. 5M). Meanwhile, both fcc Cu and IrNi@Cuso meet much larger RDS barriers at the reduction of NO₂* to NO* of 0.99 and 1.29 eV, respectively, limiting the reaction at the generation of NO₂_{^{−}} as the main products of NO₃RR. In addition, for the competition generation of both NH₂OH* and NH* from NHOH*, both pathways are energetically preferred on IrNiCu@Cu-20, supporting the experimental characterizations. However, fcc Cu and IrNiCu@Cu-30 only prefer the reaction pathway through NH* due to the higher energy costs for the formation of NH₂OH*, decreasing the formation trends towards NH₃. As the competitive reaction, the reaction trend of HER is also investigated, where IrNiCu@Cu-20 meets the largest energy barrier due to the overbinding of protons (FIG. 5n). The energy barrier for HER is reduced on IrNiCu@Cu-30 and fcc Cu, which also affects the selectivity towards the NO₃RR.

### Demonstration of Zn-Nitrate Battery

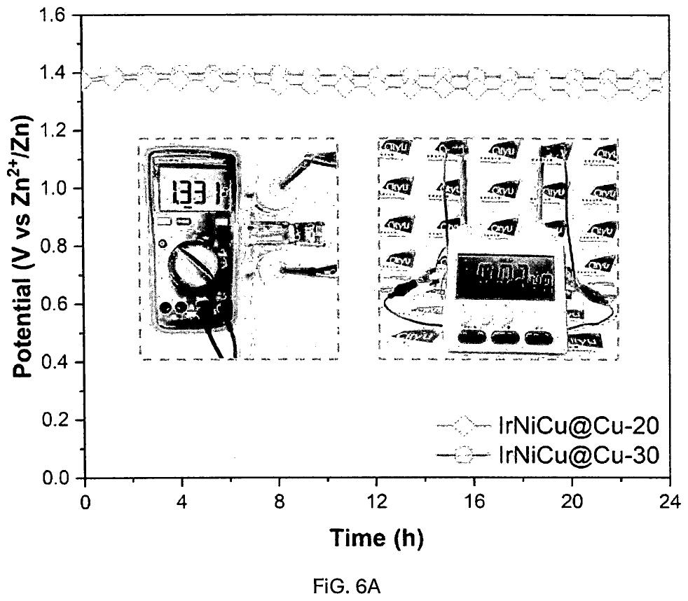

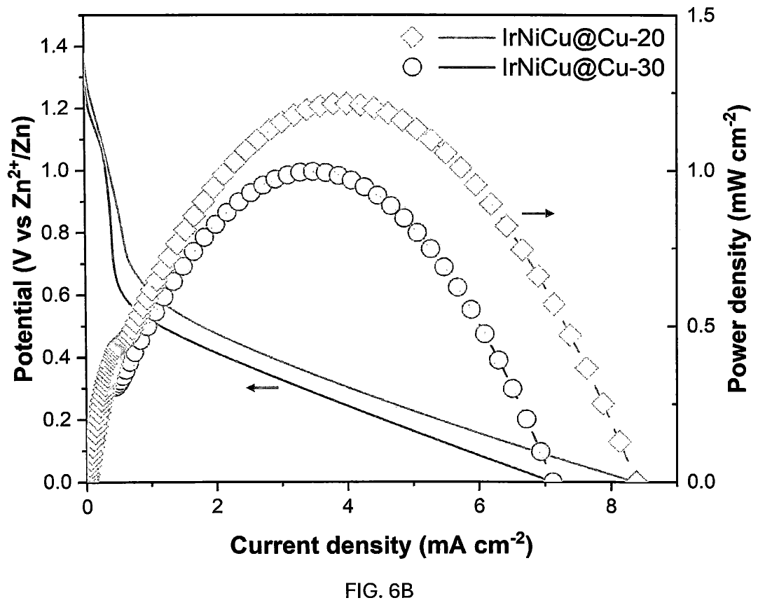

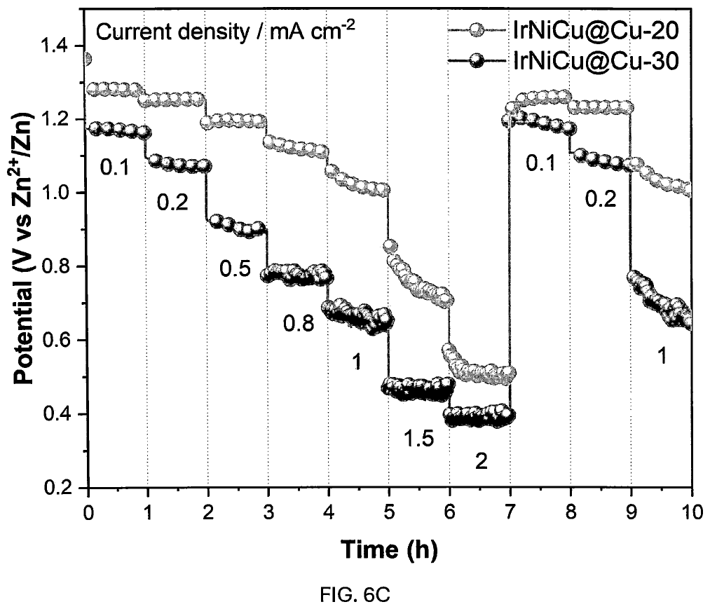

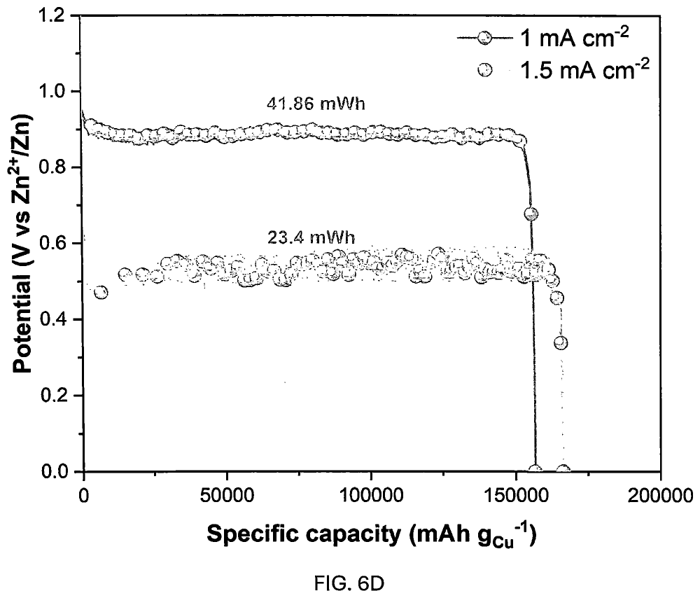

Benefited from the positive onset potential of IrNiCu@Cu nanostructures, the assembled Zn-NO₃_{^{−}} batteries using Zn as the anode demonstrate relatively high open-circuit voltage (OCV) of around 1.4 V (vs Zn²⁺/Zn) for IrNiCu@Cu-20 and IrNiCu@Cu-30, and the OCV is stable for 24 h without disturbance (FIG. 6A). Meanwhile, Zn-NO₃_{^{−}} battery holds potential to be used as a power source to drive electronic devices, such as electronic timer. As shown in FIG. 6B, the typical discharging polarization curve of this battery system reveals a peak power density (Pₘₐₓ) of 1.21 mW cm⁻² at 0.3 V (vs Zn²⁺/Zn) when using IrNiCu@Cu-20 as the cathode. By further optimizing the catholyte composition to lower the solution resistance, a higher Pmax of 2.54 mW cm⁻² is achieved (FIG. 32), and the Pₘₐₓ of 3.3 mW cm⁻² is obtained in catholyte containing 1 M NO₃_{^{−}} with enhanced mass transfer (FIGS. 33A-33B). The Zn-NO₃_{^{−}} battery performance using IrNiCu@Cu-20 as the cathode is also comparable to other emerging electrocatalysts (Table 3). After replacing IrNiCu@Cu-20 with IrNiCu@Cu-30, Pₘₐₓ drops to 1 mW cm⁻² at 0.29 V (vs Zn²⁺/Zn). Furthermore, the rate performance of IrNiCu@Cu nanostructures during discharging is quite different. IrNiCu@Cu-20 brings higher discharge plateaus at the same current density in comparison with IrNiCu@Cu-30. To be specific, the discharge plateaus are about 1.29, 1.25, 1.20, 1.12, 1.02, 0.76, and 0.51 V (vs Zn²⁺/Zn) at 0.1, 0.2, 0.5, 0.8, 1.0, 1.5 and 2.0 mA cm 2 for IrNiCu@Cu-20, respectively (FIG. 6C). When the current density decreases to the original level, the working voltage also recovers to the initial state, indicating that IrNiCu@Cu-20 can tolerate high current impact. Besides, for IrNiCu@Cu-20 cathode, the constructed Zn-NO₃_{^{−}} battery can release a total electrical energy of 41.86 mWh at the discharging current density of 1 mA cm⁻², which corresponds to a high energy density of 71555.6 Wh kg_{cat}⁻¹, and full discharging at 1.5 mA cm 2 leads to a lower output voltage with lower electrical energy of 23.4 mWh (FIG. 6D). In general, Zn-NO₃_{^{−}} galvanic cell can act as a power supply with a delicate design of cathode materials.

### Discussions

In the present invention, unconventional phase (hexagonal close-packed phase-hcp) Cu, i.e., 2H Cu structure, has been successfully obtained through epitaxial growth on a hcp IrNi template. Importantly, the distribution of unconventional phase Cu evolved into different configurations by adjusting the growth time, resulting in different performance towards nitrate reduction and Zn-nitrate batteries. In particular, IrNiCu@Cu-20 with Cu nano-islands on the template displayed a better selectivity toward NH₃, with the highest NH₃ FE of 86% at −0.1 V (vs RHE) in alkaline media, proved by in-situ DEMS which captured the signals of important intermediates (i.e., HNO and NH₂OH). Meanwhile, the NH₃ yield rate reached up to 687.3 mmol g_{Cu}⁻¹ h⁻¹. In contrast, the main product for IrNiCu@Cu-30 and IrNiCu@Cu-50 with a larger Cu coverage on IrNi surface was NO₂_{^{−}}, with NO₂_{^{−}} FE up to 61.8% and 71.7% at 0.1 V (vs RHE), respectively. Furthermore, DFT calculations have unraveled distinct electronic structures induced by the structure of the surface Cu layers, where IrNi@Cu₂₀ has the highest d-band center for surface Cu sites to guarantee the strong adsorptions of key intermediates. The optimal electronic structures of IrNi@Cu₂₀ supply the fast conversion of key intermediates, which reduces the energy barriers towards the generation of NH₃. IrNi@Cu₂₀ with low-coordinated Cu sites also suggest the potential of coordination environment regulation toward Cu sites for enhanced nitrate reduction. In all, controlling the distribution of unconventional phase Cu or Cu coverage at the catalytic interface provides an effective strategy to regulate the NO₃RR performance towards practical applications.

As mentioned above, electrocatalysts play a key role in optimizing the performance of NO₃RR to realize high NH₃ generation rate, high NHs selectivity and high energy efficiency. Currently, metal-based catalysts have been extensively studied owing to their superior activity toward nitrate reduction, with several materials factors (e.g., defect, crystallinity, strain, and facet) explored to uncover the structure-property relationship of electrocatalysts. For example, oxygen vacancies were introduced into TiO₂ to obtain an enhanced NH₃ Faradaic efficiency (FE) of 85%, as the oxygen vacancy could accommodate the oxygen atom in nitrate to weaken the N—O bond.[²³] Besides, metal vacancies were created in WSe₂₋ₓ, and unsaturated W sites showed stronger adsorption towards nitrate. In addition, amorphous RuO₂ with a modified d-band center holds a lower reaction energy barrier of *NO hydrogenation than crystallized RuO₂. In another study, strained Ru nanoclusters reported by Yu et al. indicate a strain-induced hydrogen radicals (⋅H) formation, which is important for nitrate protonation. Generally, regulating the structural parameters of metal-based catalysts will alter the interaction between reactant and catalysis interface, thus leading to a promoted NO₃_{^{−}}-to-NH₃ conversion.

Crystal phase, which refers to the atomic arrangement in a material to form a long-range ordered structure, is also an important material factor that can greatly affect the catalytic reactions. Metal nanomaterials with unconventional phases or heterophases have displayed lower overpotential and higher specific activity for a series of reactions, including hydrogen evolution reaction (HER), alcohol oxidation, carbon dioxide reduction reaction (CO₂RR). 4H/face-centered cubic (fcc) Au@Cu exhibits enhanced overall activity and better ethylene selectivity in CO₂RR. Recently, 4H/fcc Ir nanostructures were reported to exhibit enhanced performance in electrochemically reversible CO₂ conversion and coupled into Li—CO₂ battery to achieve a high energy efficiency up to 84%. However, the effect of phase has seldomly been explored in NO₃RR. Copper (Cu) has partially filled d orbital, resulting in strong affinity toward nitrate molecule and activation of N═O bond. Considering Cu is effective in catalyzing the potential determining step of NO₃RR, i.e., nitrate reduction to nitrite (NO₂_{^{−}}), and inhibiting the formation of H₂, Cu-based electrocatalysts have been proved efficient towards NO₃RR.^{[42-44]} Nevertheless, given the harsh synthesis condition and easy oxidation of Cu under ambient environment, catalysts with unconventional phase Cu have not been reported for nitrate reduction.

In the present invention, unconventional phase 2H Cu is obtained via epitaxial growth on hexagonal close-packed (hcp) IrNi nanobranches, and explicit structure-performance relation is presented to uncover the importance of rationally designed Cu sites in NO₃RR. During the reduction process, Cu atom will diffuse into the template and form a ternary IrNiCu alloy, and the distribution of 2H Cu on IrNi surface can be modulated elaborately by reaction time, leading to controllable product distribution after nitrate reduction. IrNi nanobranches with dispersed 2H—Cu nano-islands (IrNiCu@Cu-20) display the highest NH₃ FE of 86% at −0.1 V (vs reversible hydrogen electrode (RHE)), with a NH₃ yield rate of 687.3 mmol g_{Cu}⁻¹ h⁻¹. However, the main product of IrNi nanobranches with almost fully covered Cu (IrNiCu@Cu-30 and IrNiCu@Cu-50) is NO₂_{^{−}} with FE up to 61.8% at 0.1 V (vs RHE). Furthermore, a tandem catalysis mechanism is discovered on IrNiCu@Cu-20, where NO₂_{^{−}} produced by Cu sites is subsequently hydrogenated on IrNi sites. Density functional theory (DFT) calculations have shown that the control of Cu growth has significant influences on the NO₃RR performance, where IrNiCu@Cu-20 has shown the highest electroactivity due to the abundant electroactive low-coordinated sites. The upshifted d-band center in IrNiCu@Cu-20 guarantees fast electron transfer for efficient generation of NH₃ by decreasing the barriers of the rate-determining step. Last but not the least, zinc (Zn)-nitrate battery is constructed, indicating that crystal phase engineering of metal-based nanostructures provides an effective strategy to regulate the performance of catalytic reactions and energy devices.

It should be understood that certain features of the invention, which are, for clarity, described in the content of separate embodiments, may be provided in combination in a single embodiment. Conversely, various features of the invention which are, for brevity, described in the content of a single embodiment, may be provided separately or in any appropriate sub-combinations. It is to be noted that certain features of the embodiments are illustrated by way of non-limiting examples. Further, when specific values or discrete parameters in, for example, an experiment are indicated, the values or parameters in the same ratio or proportion will be considered as understood by a skilled person as equally workable.

### Tables

TABLE 1
A summary of EXAFS fitting results of IrNi, IrNiCu@Cu-20,
IrNiCu@Cu-30, IrNiCu@Cu-50, and fcc Cu NPs.

| | Scattering | | | | | |
|---|---|---|---|---|---|---|
| Sample | path | CN | σ² (Å²) | ΔE₀ (eV) | R (Å) | R-factor |
| IrNi | Ni—Ni | 8.9 | 0.0109 | −2.78 | 2.62 | 0.011 |
| | Ni—Ir | 0.7 | 0.0065 | −2.78 | 2.59 | |
| | Ir—Ni | 5.1 | 0.0065 | 9.51 | 2.59 | |
| | Ir—Ir | 4.9 | 0.0065 | 9.51 | 2.66 | |
| IrNiCu@Cu- | Ni—Ni | 10.6 | 0.0111 | −3.10 | 2.62 | 0.009 |
| 20 | Ni—Ir | 0.6 | 0.0057 | −3.10 | 2.59 | |
| | Ir—Ni | 4.9 | 0.0057 | 8.26 | 2.59 | |
| | Ir—Ir | 6.0 | 0.0057 | 8.26 | 2.66 | |
| | Cu—O | 2.3 | 0.0057 | 6.48 | 1.95 | 0.007 |
| | Cu—Cu1 | 2.5 | 0.0076 | −2.87 | 2.54 | |
| | Cu—Cu2 | 0.9 | 0.0076 | −2.87 | 2.93 | |
| IrNiCu@Cu- | Ni—Ni | 11.2 | 0.0113 | 3.60 | 2.62 | 0.019 |
| 30 | Ni—Ir | 0.6 | 0.0053 | 3.60 | 2.61 | |
| | Ir—Ni | 4.9 | 0.0053 | 9.37 | 2.61 | |
| | Ir—Ir | 7.1 | 0.0053 | 9.37 | 2.68 | |
| | Cu—O | 1.1 | 0.0078 | 5.22 | 1.92 | 0.002 |
| | Cu—Cu | 6.9 | 0.0085 | −0.92 | 2.54 | |
| IrNiCu@Cu- | Ni—Ni | 11.4 | 0.0114 | −3.55 | 2.62 | 0.014 |
| 50 | Ni—Ir | 0.6 | 0.0051 | −3.55 | 2.59 | |
| | Ir—Ni | 5.5 | 0.0051 | 6.76 | 2.59 | |
| | Ir—Ir | 5.3 | 0.0051 | 6.76 | 2.65 | |
| | Cu—O | 1.4 | 0.0078 | 5.79 | 1.93 | 0.002 |
| | Cu—Cu | 5.9 | 0.0082 | −0.38 | 2.55 | |
| Cu NPs | Cu—O | 0.9 | 0.0054 | 5.63 | 1.90 | 0.002 |
| | Cu—Cu | 5.1 | 0.0083 | 0.69 | 2.54 | |
| Ni foil | Ni—Ni | 12 | 0.0061 | −0.01 | 2.48 | 0.001 |
| Ir powder | Ir—Ir | 12 | 0.0034 | 7.75 | 2.71 | 0.007 |
| Cu foil | Cu—Cu | 12 | 0.0085 | −1.00 | 2.54 | 0.001 |

TABLE 2
A comparison of the electrochemical nitrate reduction performance of IrNiCu@Cu-20
with other reported electrocatalysts in alkaline and neutral media.

| | | Potential | NH₃ | | |
|---|---|---|---|---|---|
| | | (V vs | FE | NH₃ yield | |
| Catalysts | Electrolytes | RHE) | (%) | rate | Refs. |
| IrNiCu@Cu-20 | 0.1M KOH + 0.1M | −0.1 | 86 | 687.3 mmol | This |
| | KNO₃ | | | g_{Cu}⁻¹ h⁻¹ | work |
| | | | | 3.07 mg cm⁻² | |
| | | | | h⁻¹ | |
| IrNiCu@Cu-20 | 0.1M KOH + 1M | −0.2 | 94.14 | 10.52 mg cm⁻² | This |
| | KNO₃ | | | h⁻¹ | work |

Alkaline media

| | | | | | |
|---|---|---|---|---|---|
| Ru₁₅Co₈₅ | 0.1M KOH + 0.1M | 0 | 97 | 54.4 mg mg⁻¹ | [16] |
| | KNO₃ | | | h⁻¹ | |
| CuCoOₓ | 0.1M KOH + 0.01M | −0.1 | 97.8 | 3.86 mg cm⁻² | [17] |
| | KNO₃ | | | h⁻¹ | |
| CuPd nanocubes | 1M KOH + 1M | −0.5 | 92.5 | 106.2 mg h⁻¹ | [18] |
| | KNO₃ | | | mg⁻¹ (−0.6 V) | |
| CuCo SP | 0.1M KOH + 0.01M | −0.175 | 93.3 | 2.64 mg cm⁻² | [19] |
| | NO₃⁻ | | | h⁻¹ | |
| Cu—N—C SAC | 0.1M KOH + 0.1M | −1.0 | 84.7 | 4.5 mg cm⁻² | [20] |
| | KNO₃ | | | h⁻¹ | |
| Fe—PPy SACs | 0.1M KOH + 0.1M | −0.7 | Nearly 100 | 2.75 mg cm⁻² | [21] |
| | KNO₃ | | | h⁻¹ | |
| Au₁Cu SAAs | 0.1M KOH + 7.14 | −0.2 | 98.7 | 0.555 mg cm⁻² | [22] |
| | mM NO₃⁻ | | | h⁻¹ | |
| Cu@C | 1M KOH +1 mM | −0.3 | 72 | 0.31 mg cm⁻² | [23] |
| | NO₃⁻ | | | h⁻¹ | |
| γ-CD-K⁺ | 0.1M KOH + 0.1M | −0.9 | 79.3 | 4.66 mg cm⁻² | [24] |
| | KNO₃ | | | h⁻¹ | |
| Cu nanodisks | 0.1M KOH + 10 | −0.5 | 81.1 | 0.91 mg mg⁻¹ | [25] |
| | mM KNO₃ | | | h⁻¹ | |
| Cu NBs (100) | 1M KOH + 0.1M | −0.15 | 95 | 650 mmol g_{cat}⁻¹ | [26] |
| | KNO₃ | | | h⁻¹ | |
| Bi nanocrystals | 1M KOH + 0.5M | −0.5 | 90.6 | ca. 12 g g_{cat}⁻¹ | [27] |
| | KNO₃ | | | h⁻¹ | |
| Gd SA on O-defect | 1M KOH + 1M | −0.2 | ca. 68% | 628 μg mg_{cat}⁻¹ | [28] |
| rich NiO | KNO₃ | | | h⁻¹ | |
| Fe₃C on N-doped C | 1M KOH + 75 | −0.5 | 96.7 | 1.19 mmol | [29] |
| nanosheet | mM KNO₃ | | | mg⁻¹ h⁻¹ | |
| FeB₂ | 1M KOH + 0.1M | −0.6 | 96.8 | 25.5 mg cm⁻² | [30] |
| | KNO₃ | | | h⁻¹ | |
| CoP—CNS on Cu foam | 1M NaOH + 1M | −1.03 | 88.6 | 8.47 mmol | [31] |
| | NaNO₃ | | | cm⁻² h⁻¹ | |

Neutral media

| | | | | | |
|---|---|---|---|---|---|
| NiO₄—CCP | 0.5M NaNO₃ + 1M | −0.7 | 94.7 | 1.83 mmol g⁻¹ | [32] |
| | Na₂SO₄ | | | h⁻¹ | |
| Fe@N—C | 500 ppm NaNO₃ + | −0.75 | 91.8 | ca. 2.25 mg | [33] |
| | 0.5M Na₂SO₄ | | | cm⁻² h⁻¹ | |
| Pd NA on nickel foam | 0.5M Na₂SO₄ + | −1.2 | 78 | 1.52 mmol | [34] |
| | 0.1M NaNO₃ | | | cm⁻² h⁻¹ | |
| Mn incorporated Co₃O₄ | 0.5M K₂SO₄ + 0.1M | −1.2 | 99.5 | 35 mg cm⁻² h⁻¹ | [35] |
| | KNO₃ | | | | |
| Cu-doped Co₃O₄ | 0.1M Na₂SO₄ + | −0.6 | 86.5 | 36.71 mmol g⁻¹ | [36] |
| | 500 ppm NO₃⁻ | | | h⁻¹ | |
| FeSA (FeN₄) | 0.5M KNO₃ + 0.1M | −0.66 | 75 | 5.245 mg | [37] |
| | K₂SO₄ | | | mg_{cat}⁻¹ h⁻¹ | |
| Cu-SA (Cu-cis-N₂O₂) | 0.5M Na₂SO₄ + | −1.6 | ca. 80 | 27.84 mg cm⁻² | [38] |
| | 1000 ppm NO₃⁻—N | | | h⁻¹ | |
| Fe—NC | 0.1M K₂SO₄ + 0.5M | −0.9 | 68 | 18.8 mg mg⁻¹ | [39] |
| | KNO₃ | | | h⁻¹ | |
| LaCoO₃ | 1M Na₂SO₄ + 0.5M | −1.0 | 91.5 | 4.18 mmol | [40] |
| | KNO₃ | | | mg⁻¹ h⁻¹ | |
| Pd-nanodot/Zr-MOF | 0.1M Na₂SO₄ + | −1.3 | 58.1 | 287.31 mmol | [41] |
| | 500 ppm NO₃⁻—N | | | g_{cat}⁻¹ h⁻¹ | |

TABLE 3
A comparison of the Zn-nitrate battery performance of
IrNiCu@Cu-20 with other reported electrocatalysts.

| | | Open | Peak | |
|---|---|---|---|---|
| | | circuit | power | |
| | | voltage | density | |
| Cathodes | Catholytes | (V) | (mW cm⁻²) | Refs. |
| IrNiCu@Cu-20 | 0.1M NO₃⁻ + 0.1M | 1.4 | 2.54 | This |
| | KOH + 0.2M K₂SO₄ | | | work |
| | 1M NO₃⁻ + 0.01M | 1.39 | 3.3 | |
| | KOH | | | |
| Pd doped TiO₂ | 0.25M LiNO₃ + 5M | 0.81 | 0.87 | [7] |
| | LiCl | | | |
| NiCOP—V_{P} | 0.1M NO₃⁻ + 1M | 1.39 | 1.14 | [42] |
| | KOH | | | |
| RhCu M-tpp | 3000 ppm NO₃⁻ + | ca. 1.52 | 1.54 | [43] |
| | 0.5M Na₂SO₄ | | | |
| RuFe NFs | 0.1M NaNO₃ + 0.5M | 1.37 | 1.9 | [44] |
| | Na₂SO₄ | | | |
| Fe doped Ni₂P | 0.05M KNO₃ + 0.2M | 1.22 | 3.25 | [45] |
| | K₂SO₄ | | | |
| Fe₂TiO₅ | 0.1M NaNO₃ + PBS | 1.5 | 5.6 | [46] |
| nanofibers | | | | |
| Metastable | 0.05M KNO₃ + 1M | 1.27 | 7.56 | [47] |
| phase Cu | KOH | | | |
| Ni SA | 200 ppm NO₃⁻—N + | 1.51 | 12.7 | [48 |
| alloyed Cu | 0.5M K₂SO₄ | | | |
| Cu nanowire | 4000 ppm NO₃⁻ + | 0.93 | 14.1 | [49] |
| | 0.1M KOH | | | |
| Ru/β-Co(OH)₂ | 0.1M KNO₃ + 1M | 1.48 | 29.87 (flow | [50] |
| | KOH | | cell) | |

### REFERENCES

The following references are incorporated in their entirety and a skilled person is considered to be aware of disclosure of these references.
X. Zhang, E. A. Davidson, D. L. Mauzerall, T. D. Searchinger, P. Dumas, Y. Shen, Nature 2015, 528, 51.
X. B. Fu, J. B. Pedersen, Y. Y. Zhou, M. Saccoccio, S. F. Li, R. Salinas, K. T. Li, S. Z. Andersen, A. N. Xu, N. H. Deissler, J. B. V. Mygind, C. Wei, J. Kibsgaard, P. C. K. Vesborg, J. K. Norskov, I. Chorkendorff, Science 2023, 379, 707.
G. Soloveichik, Nat. Catal. 2019, 2, 377.
V. Kyriakou, I. Garagounis, A. Vourros, E. Vasileiou, M. Stoukides, Joule 2020, 4, 142.
Y. Xiong, Y. Wang, J. Zhou, F. Liu, F. Hao, Z. Fan, Adv. Mater. 2023, 35, 2304021.
H. Xu, Y. Ma, J. Chen, W. X. Zhang, J. Yang, Chem. Soc. Rev. 2022, 51, 2710.
P. H. van Langevelde, I. Katsounaros, M. T. M. Koper, Joule 2021, 5, 290.
W. Chen, X. Yang, Z. Chen, Z. Ou, J. Hu, Y. Xu, Y. Li, X. Ren, S. Ye, J. Qiu, J. Liu, Q. Zhang, Adv. Funct. Mater. 2023, 33, 2300512.
Y. Wang, C. Wang, M. Li, Y. Yu, B. Zhang, Chem. Soc. Rev. 2021, 50, 6720.
R. Hao, L. Tian, C. Wang, L. Wang, Y. Liu, G. Wang, W. Li, G. A. Ozin, Chem Catal. 2022, 2, 622.
D. M. Miller, K. Abels, J. Guo, K. S. Williams, M. J. Liu, W. A. Tarpeh, J. Am. Chem. Soc. 2023, 145, 19422.
D. M. Miller, M. J. Liu, K. Abels, A. Kogler, K. S. Williams, W. A. Tarpeh, Energy Environ. Sci. 2024, 17, 5691.
J. Y. Fang, Q. Z. Zheng, Y. Y. Lou, K. M. Zhao, S. N. Hu, G. Li, O. Akdim, X. Y. Huang, S. G. Sun, Nat. Commun. 2022, 13, 7899.
Q. Gao, H. S. Pillai, Y. Huang, S. Liu, Q. Mu, X. Han, Z. Yan, H. Zhou, Q. He, H. Xin, H. Zhu, Nat. Commun. 2022, 13, 2338.
W. He, J. Zhang, S. Dieckhofer, S. Varhade, A. C. Brix, A. Lielpetere, S. Seisel, J. R. C. Junqueira, W. Schuhmann, Nat. Commun. 2022, 13, 1129.
F. Y. Chen, Z. Y. Wu, S. Gupta, D. J. Rivera, S. V. Lambeets, S. Pecaut, J. Y. T. Kim, P. Zhu, Y. Z. Finfrock, D. M. Meira, G. King, G. Gao, W. Xu, D. A. Cullen, H. Zhou, Y. Han, D. E. Perea, C. L. Muhich, H. Wang, Nat. Nanotechnol. 2022, 17, 759.
Z. Y. Wu, M. Karamad, X. Yong, Q. Huang, D. A. Cullen, P. Zhu, C. Xia, Q. Xiao, M. Shakouri, F. Y. Chen, J. Y. T. Kim, Y. Xia, K. Heck, Y. Hu, M. S. Wong, Q. Li, I. Gates, S. Siahrostami, H. Wang, Nat. Commun. 2021, 12, 2870.
S. Han, H. Li, T. Li, F. Chen, R. Yang, Y. Yu, B. Zhang, Nat. Catal. 2023, 6, 402.
G.-F. Chen, Y. Yuan, H. Jiang, S.-Y. Ren, L.-X. Ding, L. Ma, T. Wu, J. Lu, H. Wang, Nat. Energy 2020, 5, 605.
Y. Wang, M. Sun, J. Zhou, Y. Xiong, Q. Zhang, C. Ye, X. Wang, P. Lu, T. Feng, F. Hao, F. Liu, J. Wang, Y. Ma, J. Yin, S. Chu, L. Gu, B. Huang, Z. Fan, Proc. Natl. Acad. Sci. U.S.A. 2023, 120, e2306461120.
R. Daiyan, T. Tran-Phu, P. Kumar, K. Iputera, Z. Tong, J. Leverett, M. H. A. Khan, A. Asghar Esmailpour, A. Jalili, M. Lim, A. Tricoli, R.-S. Liu, X. Lu, E. Lovell, R. Amal, Energy Environ. Sci. 2021, 14, 3588.
T. S. Bui, E. C. Lovell, R. Daiyan, R. Amal, Adv. Mater. 2023, 35, 2205814.
R. Jia, Y. Wang, C. Wang, Y. Ling, Y. Yu, B. Zhang, A C S Catal. 2020, 10, 3533.
Y. Wang, H. Li, W. Zhou, X. Zhang, B. Zhang, Y. Yu, Angew. Chem. Int. Ed. 2022, 61, e202202604.
J. Li, G. Zhan, J. Yang, F. Quan, C. Mao, Y. Liu, B. Wang, F. Lei, L. Li, A. W. M. Chan, L. Xu, Y. Shi, Y. Du, W. Hao, P. K. Wong, J. Wang, S. X. Dou, L. Zhang, J. C. Yu, J. Am. Chem. Soc. 2020, 142, 7036.
L.-F. Chen, A.-Y. Xie, Y.-Y. Lou, N. Tian, Z.-Y. Zhou, S.-G. Sun, J. Electroanal. Chem. 2022, 907, 116022.
J. Lim, C.-Y. Liu, J. Park, Y.-H. Liu, T. P. Senftle, S. W. Lee, M. C. Hatzell, A C S Catal. 2021, 11, 7568.
Y. Fu, S. Wang, Y. Wang, P. Wei, J. Shao, T. Liu, G. Wang, X. Bao, Angew. Chem. Int. Ed. 2023, 62, e202303327.
F. Liu, Z. Fan, Chem. Soc. Rev. 2023, 52, 1723.
P. Shen, G. Wang, K. Chen, J. Kang, D. Ma, K. Chu, J. Colloid Interf. Sci. 2023, 629, 563.
H. Li, X. Zhou, W. Zhai, S. Lu, J. Liang, Z. He, H. Long, T. Xiong, H. Sun, Q. He, Z. Fan, H. Zhang, Adv. Energy Mater. 2020, 10, 2002019.
S. Lu, J. Liang, H. Long, H. Li, X. Zhou, Z. He, Y. Chen, H. Sun, Z. Fan, H. Zhang, Acc. Chem. Res. 2020, 53, 2106.
Y. Wang, F. Hao, M. Sun, M. T. Liu, J. Zhou, Y. Xiong, C. Ye, X. Wang, F. Liu, J. Wang, P. Lu, Y. Ma, J. Yin, H. C. Chen, Q. Zhang, L. Gu, H. M. Chen, B. Huang, Z. Fan, Adv. Mater. 2024, 36, e2313548.
Z. Fan, M. Bosman, Z. Huang, Y. Chen, C. Ling, L. Wu, Y. A. Akimov, R. Laskowski, B. Chen, P. Ercius, J. Zhang, X. Qi, M. H. Goh, Y. Ge, Z. Zhang, W. Niu, J. Wang, H. Zheng, H. Zhang, Nat. Commun. 2020, 11, 3293.
Z. Fan, M. Bosman, X. Huang, D. Huang, Y. Yu, K. P. Ong, Y. A. Akimov, L. Wu, B. Li, J. Wu, Y. Huang, Q. Liu, C. E. Png, C. L. Gan, P. Yang, H. Zhang, Nat. Commun. 2015, 6, 7684.
X. Zhou, Y. Ma, Y. Ge, S. Zhu, Y. Cui, B. Chen, L. Liao, Q. Yun, Z. He, H. Long, L. Li, B. Huang, Q. Luo, L. Zhai, X. Wang, L. Bai, G. Wang, Z. Guan, Y. Chen, C. S. Lee, J. Wang, C. Ling, M. Shao, Z. Fan, H. Zhang, J. Am. Chem. Soc. 2022, 144, 547.
Y. Ge, Z. Huang, C. Ling, B. Chen, G. Liu, M. Zhou, J. Liu, X. Zhang, H. Cheng, G. Liu, Y. Du, C. J. Sun, C. Tan, J. Huang, P. Yin, Z. Fan, Y. Chen, N. Yang, H. Zhang, J. Am. Chem. Soc. 2020, 142, 18971.
Y. Chen, Z. Fan, Z. Luo, X. Liu, Z. Lai, B. Li, Y. Zong, L. Gu, H. Zhang, Adv. Mater. 2017, 29.
D. Yu, L. Gao, T. Sun, J. Guo, Y. Yuan, J. Zhang, M. Li, X. Li, M. Liu, C. Ma, Q. Liu, A. Pan, J. Yang, H. Huang, Nano Lett. 2021, 21, 1003.
Y. Chen, Z. Fan, J. Wang, C. Ling, W. Niu, Z. Huang, G. Liu, B. Chen, Z. Lai, X. Liu, B. Li, Y. Zong, L. Gu, J. Wang, X. Wang, H. Zhang, J. Am. Chem. Soc. 2020, 142, 12760.
J. Zhou, T. Wang, L. Chen, L. Liao, Y. Wang, S. Xi, B. Chen, T. Lin, Q. Zhang, C. Ye, X. Zhou, Z. Guan, L. Zhai, Z. He, G. Wang, J. Wang, J. Yu, Y. Ma, P. Lu, Y. Xiong, S. Lu, Y. Chen, B. Wang, C. S. Lee, J. Cheng, L. Gu, T. Zhao, Z. Fan, Proc. Natl. Acad. Sci. U.S.A. 2022, 119, e2204666119.
Y. Yao, L. Zhang, Sci. Bull. 2022, 67, 1194.
Y. Wang, A. Xu, Z. Wang, L. Huang, J. Li, F. Li, J. Wicks, M. Luo, D. H. Nam, C. S. Tan, Y. Ding, J. Wu, Y. Lum, C. T. Dinh, D. Sinton, G. Zheng, E. H. Sargent, J. Am. Chem. Soc. 2020, 142, 5702.
Z. Ren, K. Shi, X. Feng, A C S Energy Lett. 2023, 8, 3658.
Y. Wang, W. Zhou, R. Jia, Y. Yu, B. Zhang, Angew. Chem. Int. Ed. 2020, 59, 5350.
J. Yang, H. Qi, A. Li, X. Liu, X. Yang, S. Zhang, Q. Zhao, Q. Jiang, Y. Su, L. Zhang, J. F. Li, Z. Q. Tian, W. Liu, A. Wang, T. Zhang, J. Am. Chem. Soc. 2022, 144, 12062.
Y. Wang, Y. Xiong, M. Sun, J. Zhou, F. Hao, Q. Zhang, C. Ye, X. Wang, Z. Xu, Q. Wa, F. Liu, X. Meng, J. Wang, P. Lu, Y. Ma, J. Yin, Y. Zhu, S. Chu, B. Huang, L. Gu, Z. Fan, Angew. Chem. Int. Ed. 2024, e202402841.
A. P. LaGrow, S. Cheong, J. Watt, B. Ingham, M. F. Toney, D. A. Jefferson, R. D. Tilley, Adv. Mater. 2013, 25, 1552.
Z. Fan, H. Zhang, Acc. Chem. Res. 2016, 49, 2841.
W. Yu, J. Yu, M. Huang, Y. Wang, Y. Wang, J. Li, H. Liu, W. Zhou, Energy Environ. Sci. 2023, 16, 2991.
M. A. Akram, B. Zhu, J. Cai, S. Qin, X. Hou, P. Jin, F. Wang, Y. He, X. Li, L. Feng, Small 2023, 19, 2206966.
Y. Xue, Q. Yu, Q. Ma, Y. Chen, C. Zhang, W. Teng, J. Fan, W. X. Zhang, Environ. Sci. Technol. 2022, 56, 14797.
Q. Hu, K. Yang, O. Peng, M. Li, L. Ma, S. Huang, Y. Du, Z. X. Xu, Q. Wang, Z. Chen, M. Yang, K. P. Loh, J. Am. Chem. Soc. 2024, 146, 668.
D. He, H. Ooka, Y. Li, Y. Kim, A. Yamaguchi, K. Adachi, D. Hashizume, N. Yoshida, S. Toyoda, S. H. Kim, R. Nakamura, Nat. Catal. 2022, 5, 798.
K. Chen, G. Wang, Y. Guo, D. Ma, K. Chu, Nano Res. 2023, 16, 8737.
J. Y. Zhu, Q. Xue, Y. Y. Xue, Y. Ding, F. M. Li, P. Jin, P. Chen, Y. Chen, A C S Appl. Mater. Inter. 2020, 12, 14064.
S. Garcia-Segura, M. Lanzarini-Lopes, K. Hristovski, P. Westerhoff, Appl. Catal. B 2018, 236, 546.
H. Yin, Z. Chen, S. Xiong, J. Chen, C. Wang, R. Wang, Y. Kuwahara, J. Luo, H. Yamashita, Y. Peng, J. Li, Chem Catal. 2021, 1, 1088.
M. T. de Groot, M. T. M. Koper, J. Electroanal. Chem. 2004, 562, 81.
Y. Guo, R. Zhang, S. C. Zhang, Y. W. Zhao, Q. Yang, Z. D. Huang, B. B. Dong, C. Y. Zhi, Energy Environ. Sci. 2021, 14, 3938.
J. Zhou, Y. Xiong, M. Sun, Z. Xu, Y. Wang, P. Lu, F. Liu, F. Hao, T. Feng, Y. Ma, J. Yin, C. Ye, B. Chen, S. Xi, Y. Zhu, B. Huang, Z. Fan, Proc. Natl. Acad. Sci. U.S.A. 2023, 120, e2311149120.

What is claimed is:

1. A method of manufacture of templates of IrNi nanobranches (NBs) in hexagonal close-packed phase (hcp), comprising the steps in the sequential order of:
adding Iridium acetylacetonate [Ir(acac)₃] and nickel acetylacetonate [Ni(acac)₂] to a combination of oleylamine (OAm)/oleic acid (OA) to form a first mixture,
subjecting the first mixture to ultrasonication to obtain a homogenous solution,
adding formaldehyde (HCHO) to the homogenous solution to form a second mixture, the second mixture being a growth solution,
placing or transferring the growth solution into a container made with an inert material or with an inert lining, and subjecting the growth solution to heating in a reactor,
cooling the growth solution,
harvesting the IrNi NB templates by subjecting the growth solution to centrifugation and washing by an oil removing agent, and
collecting the IrNi NB templates by re-dispersing the IrNi NB templates in a solvent of ethanol.

2. A method as claimed in claim 1, wherein:
the HCHO solution is added to the homogenous solution dropwise under stirring or agitation.

3. A method as claimed in claim 1, wherein the oil removing agent is a mixture of ethanol and hexane with a volume ratio of 2:1 to 1:2 and the centrifugation and washing are conducted 3-4 times.

4. A method as claimed in claim 3, wherein the oil removing agent is a mixture of ethanol and hexane with a volume ratio of 1:2 and the centrifugation and washing are conducted 3 times.

5. A method as claimed in claim 1, wherein:
the weight ratio of the Ir(acac)₃ and Ni(acac)₂ is 1.1:1 to 1:1.1,
the volume ratio of the OAm and OA is 7.3:1 to 9:1,
the ultrasonication lasts for 1.5-3 hours,
the amount of the HCHO solution used is 90-00 μL, and
the growth solution is heated in the reactor from room temperature to a temperature of 200° C.-220° C. and the temperature is maintained for 10-16 hours.

6. A method as claimed in claim 5, wherein:
the weight ratio of the Ir(acac)3 and Ni(acac)2 is 1:1,
the volume ratio of the OAm and OA is 7.3:1,
the ultrasonication lasts for 2 hours,
the amount of the HCHO solution used is 100 μL, and
the growth solution is heated in the reactor from room temperature to a temperature of 220° C. and the temperature is maintained for 14 hours.

7. A method of manufacture of IrNiCu@Cu nanostructures with Cu in a hexagonal close-packed phase (hcp),
comprising firstly, in the sequential order of:
preparing templates of hexagonal close-packed phase (hcp) of IrNi nanobranches (NBs), the preparing including the steps in the sequential order of:
adding Iridum acetylacetonate [Ir(acac)₃] and nickel acetylacetonate [Ni(acac)₂] to a combination of oleylamine (OAm)/oleic acid (OA) to form a first mixture,
subjecting the first mixture to ultrasonication to obtain a homogenous solution,
adding formaldehyde (HCHO) to the homogenous solution to form a second mixture, the second mixture being a growth solution,
placing or transferring the growth solution into a container made with an inert material or with an inert lining, and subjecting the growth solution to heating in a reactor,
cooling the growth solution,
harvesting the IrNi NB templates by subjecting the growth solution to centrifugation and washing by an oil removing agent, and
collecting the IrNi NB templates by re-dispersing the IrNi NB templates in a solvent of ethanol; and
further comprising, secondly, in the sequential order of:
obtaining a predetermined quantity of the IrNi NB templates,
removing the ethanol solvent in which the IrNi NB templates are suspended by way of centrifugation,
adding OAm and copper acetylacetonate [Cu(acac)₂] to the IrNi NB templates and forming a homogenous solution,
mixing a reducing agent to the homogenous solution to reduce the Cu(acac)₂ solution to Cu, wherein the mixing is conducted by way of oscillation and not ultrasonification,
heating the homogenous solution to a predetermined temperature for a predetermined heating duration,
allowing growth of the IrNiCu@Cu nanostructures, and
isolating reaction products from the homogenous solution by way of centrifugation and/or washing with an oil removing agent, the reaction products being the IrNiCu@Cu nanostructures.

8. A method as claimed in claim 7, wherein:
the IrNi NB templates has a mass concentration of 1.8-2 mg mL⁻¹, and the amount of the IrNi NB templates is 180-200 μL,
the centrifugation to remove the ethanol solvent is conducted with a speed of 90,000-10,000 rpm for 2-3 mins,
the quantity of OAm is 1.4-1.5 mL and the concentration and quantity of Cu(acac)₂ solution are 80-120 UL and 8-10 mM respectively,
the quantity of the reducing agent is 80-100 μL,
the predetermined temperature to which the homogenous solution is heated is 150-120° C. and the predetermined heating duration of 20-50 mins
the volume ratio of ethanol and n-hexane in the ethanol and n-hexane is 8:1 to 9:1.

9. A method as claimed in claim 8, wherein:
the IrNi NB templates has a mass concentration of 2 mg mL⁻¹, and the amount of the IrNi NB templates is 200 μL,
the centrifugation to remove the ethanol solvent is conducted with a speed of 10,000 rpm for 2 mins,
the quantity of OAm is 1.5 mL, and the concentration and quantity of Cu(acac)₂ solution are 100 μL and 10 mM, respectively,
the quantity of the reducing agent is 100 μL, and
the volume ratio of ethanol and n-hexane in the ethanol and n-hexane is 9:1.

10. A method as claimed in claim 8, wherein the predetermined heating time is 20 mins, 30 mins, or 40 mins.

11. A method as claimed in claim 8, wherein the predetermined heating time is 20 mins.

12. A method as claimed in claim 8, wherein the predetermined heating time is 30 mins.

13. A method as claimed in claim 8, wherein the predetermined heating time is 40 mins.

14. A method of making an electrode provided with an electrocatalyst of IrNiCu@Cu nanostructures made from a method as claimed in claim 8, comprising a step of coating the IrNiCu@Cu nanostructure electrocatalyst on the electrode.

15. A method of enhancing the performance of electrochemical nitrate reduction reaction (NO₃RR), comprising a step of effecting the NO₃RR by using an electrode made from a method of claim 14.
